(19) United States
(12) Patent Application Publication
(10) Pub. No.: US 2024/0186291 A1
(43) Pub. Date: Jun. 6, 2024

(54) SEMICONDUCTOR DIE STACK STRUCTURE

(71) Applicant: SK hynix Inc., Icheon-si Gyeonggi-do (KR)

(72) Inventors: Sung Kyu KIM, Icheon-si Gyeonggi-do (KR); Jong Yeon KIM, Icheon-si Gyeonggi-do (KR); Song NA, Icheon-si Gyeonggi-do (KR); Sang Hyuk LIM, Icheon-si Gyeonggi-do (KR); Jong Oh KWON, Icheon-si Gyeonggi-do (KR); Jin Woo PARK, Icheon-si Gyeonggi-do (KR)

(73) Assignee: SK hynix Inc., Icheon-si Gyeonggi-do (KR)

(21) Appl. No.: 18/346,674

(22) Filed: Jul. 3, 2023

(30) Foreign Application Priority Data
Dec. 5, 2022 (KR) 10-2022-0167494

(51) Int. Cl. H01L 25/065; H01L 21/768; H01L 23/00; H01L 23/373; H01L 23/522

(52) U.S. Cl. CPC H01L 25/0657; H01L 21/76871; H01L 23/373; H01L 23/5226; H01L 24/05; H01L 2224/0508; H01L 2224/05553

(57) ABSTRACT

A semiconductor die stack structure includes a base die, a plurality of semiconductor die stack units, and bumps. Each of the plurality of semiconductor die stack units includes a lower semiconductor die and an upper semiconductor die. Each of the lower semiconductor die and the upper semiconductor die includes a body and a front-side pad structure. The front-side pad structure includes a front-side pad seed layer and a front-side pad pattern. The front-side pad pattern includes a first front-side pad portion, a second front-side pad portion, and a third front-side pad portion. The first front-side pad portion and the second front-side pad portion forms a staircase. The first front-side pad portion and the third front-side pad form a reverse staircase. The first front-side pad portion, the second front-side pad portion, and the third front-side pad include a same metal.

### CROSS-REFERENCE TO RELATED APPLICATION

The present application claims priority under 35 U.S.C. § 119(a) to Korean Patent Application No. 10-2022-0167494, filed on Dec. 5, 2022, in the Korean Intellectual Property Office, which is incorporated herein by reference in its entirety.

### BACKGROUND

### 1. Field

The present disclosure relates to a semiconductor die having a front-side pad structure and a back-side pad structure, a semiconductor die stack unit having the semiconductor die, a semiconductor die stack structure having the semiconductor die stack unit, and a high-bandwidth memory having the semiconductor die stack structure.

### 2. Description of the Related Art

A high-bandwidth memory includes a plurality of stacked semiconductor dies. As the number of stacked semiconductor dies increases, heat dissipation problems and bonding problems emerge as problems to be solved.

### SUMMARY

A semiconductor die stack structure includes a base die, a plurality of semiconductor die stack units stacked over the base die, and bumps between the base die and the plurality of semiconductor die stack units and between the plurality of semiconductor dies stack units. Each of the plurality of semiconductor die stack units includes a lower semiconductor die and an upper semiconductor die stacked over the lower semiconductor die. Each of the lower semiconductor die and the upper semiconductor die includes a body having a front-side and a back-side, and a front-side pad structure disposed over the front-side of the body. The front-side pad structure includes a front-side pad seed layer and a front-side pad pattern over the front-side pad seed layer. The front-side pad pattern includes a first front-side pad portion having a plate shape, a second front-side pad portion over the first front-side pad portion, wherein the first front-side pad portion and the second front-side pad portion forms a staircase, and a third front-side pad portion under the first front-side pad portion. The first front-side pad portion and the third front-side pad form a reverse staircase. The first front-side pad portion, the second front-side pad portion, and the third front-side pad include a same metal.

A semiconductor die stack structure includes a base die, a plurality of semiconductor die stack units stacked over the base die, and bumps between the base die and the plurality of semiconductor die stack units and between the plurality of semiconductor die stack units. Each of the plurality of semiconductor die stack units includes a lower semiconductor die and an upper semiconductor die stacked over the lower semiconductor die. Each of the lower semiconductor die and the upper semiconductor die includes a body having a front-side and a back-side, and a back-side passivation layer under the back-side of the body, and a back-side pad structure under the back-side passivation layer. The back-side pad structure includes a back-side pad seed layer under the back-side of the body, and a back-side pad pattern under the back-side pad seed layer. The back-side pattern includes a first back-side pad portion having a plate shape, and a second back-side pad portion under the first back-side pad portion. The first back-side pad portion and the second back-side pad portion form a reverse staircase. The first back-side pad portion and the second back-side pad portion include a same metal.

### BRIEF DESCRIPTION OF THE DRAWINGS

FIG. 1 is a side cross-sectional view illustrating a semiconductor die according to an embodiment of the present disclosure.

FIG. 2A is an enlarged view of an area A of FIG. 1, and FIG. 2B is a perspective view of the area A.

FIG. 3A is an enlarged view of a region B of FIG. 1, and FIG. 3B is a perspective view of the region B.

FIGS. 4A and 4B are side views comparing sizes of the front-side pad patterns and the back-side pad patterns according to embodiments of the present disclosure.

FIG. 5A is a side cross-sectional view illustrating a semiconductor die according to an embodiment of the present disclosure, FIG. 5B is an enlarged view of a region C of FIG. 5A, and FIG. 5C is an enlarged view of a region D of FIG. 5A.

FIG. 6A is a side cross-sectional view illustrating a semiconductor die according to an embodiment of the present disclosure, and FIGS. 6B to 6D are perspective views of front-side pad structures, back-side pad structures, top metal patterns and through-vias of FIG. 6A.

FIGS. 7A to 7D are side cross-sectional views illustrating semiconductor die stack units according to embodiments of the present disclosure.

FIGS. 8A and 8B are perspective views illustrating a front-side pad structure and a back-side pad structure according to embodiments of the present disclosure. FIG. 8C is a simplified perspective view illustrating shapes in which the front-side pad patterns and the back-side pad patterns are aligned with and bonded to each other.

FIGS. 9A to 9D are side cross-sectional views illustrating semiconductor die stack structures according to embodiments of the present disclosure.

FIG. 10 is a side cross-sectional view illustrating a high-bandwidth memory according to an embodiment of the present disclosure.

FIGS. 11A to 11R are side cross-sectional views illustrating a method of manufacturing a semiconductor die according to an embodiment of the present disclosure.

FIGS. 12A to 12G are views illustrating a method of forming a semiconductor die stack unit according to an embodiment of the present disclosure.

FIGS. 13A to 13C are side cross-sectional views illustrating methods of forming semiconductor die stack structures according to embodiments of the present disclosure.

### DETAILED DESCRIPTION

Some embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be enabling to those skilled in the art. Throughout the disclosure, like reference numerals refer to like parts throughout the various figures and embodiments of the present disclosure.

It will be understood that, although the terms “first” and/or “second” may be used herein to describe various elements, these elements should not be limited by these terms. These terms are only used to distinguish one element from another element, and not to imply a number or order of elements. For instance, a first element discussed below could be termed a second element without departing from the disclosure of the present disclosure. Similarly, the second element could also be termed the first element.

Other expressions that explain the relationship between elements, such as “between”, “directly between”, “adjacent to” or “directly adjacent to” should be construed in the same way.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

An embodiment of the present disclosure provides a semiconductor die including a pad structure having an enlarged volume.

An embodiment of the present disclosure provides a semiconductor die stack unit including two semiconductor dies.

An embodiment of the present disclosure provides a semiconductor die stack structure including the semiconductor die stack unit.

An embodiment of the present disclosure provides a high-bandwidth memory including the semiconductor die stack structure.

An embodiment of the present disclosure provides a method of manufacturing semiconductor dies each including a pad structure having an enlarged volume.

An embodiment of the present disclosure provides a method of manufacturing semiconductor die stack units including two semiconductor dies.

An embodiment of the present disclosure provides a method of manufacturing a semiconductor die stack structure including the semiconductor die stack unit.

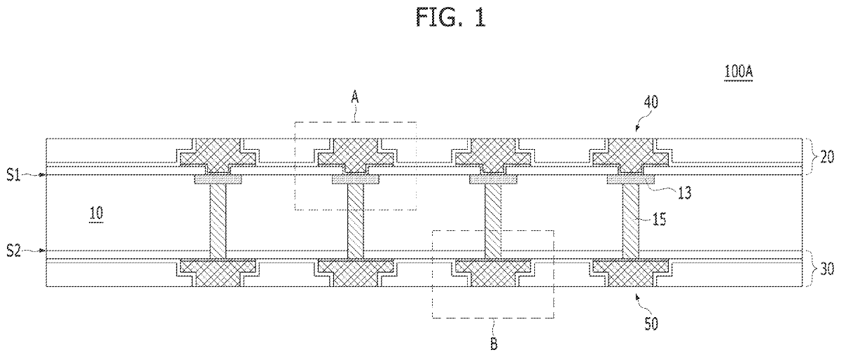

FIG. 1 is a side cross-sectional view illustrating a semiconductor die 100A according to an embodiment of the present disclosure. Referring to FIG. 1, the semiconductor die 100A may include a body 10 having a front-side S1 and a back-side S2, a front-side insulating layer structure 20 and a front-side pad structure 40 on the front-side S1 of the body 10, and a back-side insulating structure 30 and a back-side pad structure 50 under the back-side S2 of the body 10, and a top metal pattern 13 and a through-via 15 in the body 10.

The body 10 may include a semiconductor substrate, and include transistors and circuit structures disposed over the semiconductor substrate. The circuit structures may include metal interconnections and metal via plugs. The semiconductor substrate may be a silicon wafer. In an embodiment, the body 10 may be one of ceramics, glass, or a printed circuit board (PCB). The front-side S1 of the body 10 may be an active surface, for example, a top surface of insulating layers covering the circuit structure disposed over an upper surface of the semiconductor substrate. The back-side S2 of the body 10 may be a lower surface of the silicon substrate on which the circuit structures are not disposed.

The front-side insulating layer structure 20 may be disposed over the front-side S1 of the body 10 to surround side surfaces of the front-side pad structure 40. The back-side insulating layer structure 30 may be disposed under the back-side S2 of the body 10 to surround side surfaces of the back-side pad structure 50.

The top metal pattern 13 may be disposed in the body 10 to electrically connect the front-side pad structure 40 to the circuit elements in the body 10. The top metal pattern 13 may be a top metal layer of the circuit structures. That is, the top metal pattern 13 may be disposed adjacent to the front-side S1 in the body 10. The top metal pattern 13 may include a metal such as aluminum (Al) or tungsten (W). A lower surface of the top metal pattern 13 may be in contact with an upper end portion of the through-via 15.

The through-via 15 may vertically pass through the body 10 to electrically connect the top metal pattern 13 to the back-side pad structure 50. The through-via 15 may include copper (Cu). In an embodiment, the through-via 15 may further include a conductive via barrier layer surrounding side surfaces of the through-via 15 and an insulating via liner surrounding side surfaces of the conductive via barrier layer. The insulating via liner may electrically insulate the through-via 15 from the body 10. For example, the insulating via liner may include a silicon oxide based insulating material or a silicon nitride-based insulating material. The conductive barrier layer may include at least one of titanium (Ti), titanium nitride (TiN), tantalum (Ta), tantalum nitride (TaN), tungsten nitride (WN), and other metallic materials.

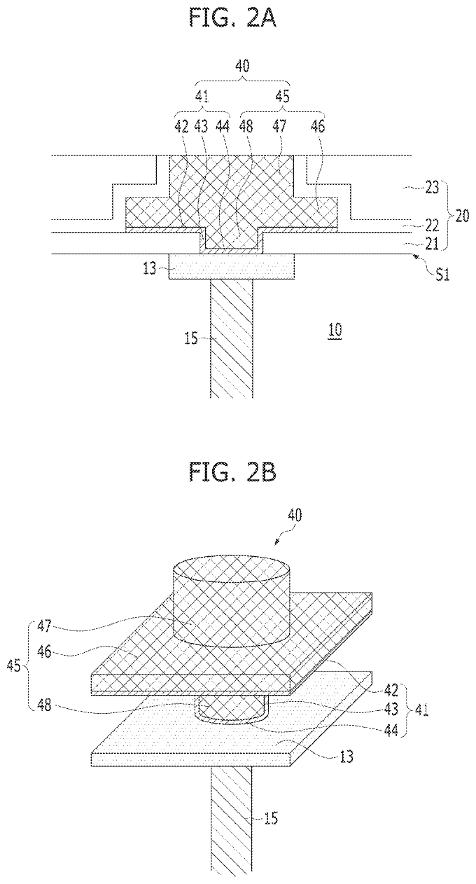

FIG. 2A is an enlarged view of an area A of FIG. 1, and FIG. 2B is a perspective view of the area A. Referring to FIGS. 2A and 2B, the front-side pad structure 40 of the semiconductor die 100A may include a front-side pad UBM (under bump metallurgy) layer 41 and a front-side pad pattern 45, and the front-side insulating layer structure 20 of the semiconductor die 100A may include a front-side passivation layer 21, a front-side pad liner 22, and a front-side insulating layer 23.

The front-side passivation layer 21 may be disposed flat on the front-side S1 of the body 10. The front-side passivation layer 21 may expose a portion of an upper surface of the top metal pattern 13. The front-side passivation layer 21 may include at least one of a silicon nitride-based insulating layer, a silicon carbon nitride-based insulating layer, or a silicon oxide-based insulating layer.

The front-side pad UBM layer 41 may be thinly and conformally disposed on the portion of the upper surface of the front-side passivation layer 21, side surfaces of the front-side passivation layer 21 exposing the upper surface of the top metal pattern 13, and the upper surface of the exposed top metal pattern 13. The front-side pad UBM layer 41 may include an adhesive layer such as titanium (Ti) or titanium tungsten (TiW), and a seed metal layer such as copper (Cu). The front-side pad UBM layer 41 may include a first front-side pad UBM portion 42 disposed on an upper surface of the front-side passivation layer 21, a second front-side pad UBM portion 43 disposed on the side surfaces of the front-side passivation layer 21 exposing the upper surface of the top metal pattern 13, and a third front-side pad UBM portion 44 disposed on the exposed top surface of the top metal pattern 13 to be horizontally extended. The first to third front-side pad UBM portions 42 to 44 may include a same material to be unified. The first front-side pad UBM portion 42 may have a horizontal plate shape. In embodiment, the first front-side pad UBM portion 42 may have a disk shape in a top view. The second front-side UBM portion 43 may vertically extent from the first front-side UBM portion 43 to the third front-side UBM portion 45. The second front-side UBM portion 43 may have a circular cylinder shape or a polygonal cylinder shape. The third front-side pad UBM portion 44 may have a recessed horizontal plate shape from the first front-side pad UBM portion 42.

The front-side pad pattern 45 may be disposed on the front-side pad UBM layer 41. The front-side pad pattern 45 may include a first front-side pad portion 46, a second front-side pad portion 47, and a third front-side pad portion 48. The first front-side pad portion 46 may be disposed on the first front-side pad UBM portion 42. For example, the first front-side pad portion 46 may have a plate shape with a flat upper surface and a vertical side surface. The first front-side pad portion 46 may have a circular shape or a polygonal shape in a top view. In the embodiment, it is illustrated that the first front-side pad portion 46 has a rectangular shape in the top view. For example, the second front-side pad portion 47 may be disposed on the first front-side pad portion 46 to have a pillar shape, or a stair shape protruding upward from the first front-side pad portion 42. That is, the second front-side pad portion 47 may have a mesa shape having a flat upper surface and a vertical side surface. That is, the first front-side pad portion 46 and the second front-side pad portion 47 may form a staircase shape. In the top view, the second front-side pad portion 47 may have a circular shape or a polygonal shape. In the embodiment, it is illustrated that the second front-side pad portion 47 has a circular shape in the top view. The third front-side pad portion 48 may be disposed to protrude downward from the first front-side pad portion 46. For example, the third front-side pad portion 48 may be disposed to have a pillar shape or a stair shape protruding downward under a lower surface of the first front-side pad portion 46. The third front-side pad portion 48 may correspond to a landing portion for the front-side pad pattern 45 to be electrically connected to the top metal pattern 13. The first front-side pad portion 46 and the third front-side pad portion 48 may form a reverse staircase shape.

The second front-side pad UBM portion 43 may be in contact with and surround a side surface of the third front-side pad portion 48. The third front-side pad UBM portion 44 may be in contact with and surround a lower surface of the third front-side pad portion 48.

The front-side pad liner layer 22 may conformally surround side surfaces and upper surfaces of the first front-side pad portion 46 and side surfaces of the second front-side pad portion 47. The front-side pad liner layer 22 may also surround side surfaces of the first front-side UBM portion 42. The front-side pad liner layer 22 may include an insulating barrier layer such as a silicon nitride layer. For example, the front-side pad liner layer 22 may include at least one of a silicon nitride layer, a silicon carbon nitride layer, a silicon oxy-nitride layer, and other silicon nitride-based layers. The front-side pad liner layer 22 may extend onto an upper surface of the front-side passivation layer 21. In a side view, the front-side pad liner layer 22 may have a staircase shape.

The front-side bonding insulating layer 23 may be disposed on the front-side pad liner layer 22 to surround side surfaces of the front-side pad structure 40. For example, the front-side bonding insulating layer 23 may fill spaces between the front-side pad structures 40. The front-side bonding insulating layer 23 may include at least one of a silicon oxide layer, a silicon nitride layer, a silicon carbon nitride layer, and other insulating layers including silicon, oxygen, and nitrogen.

An upper surface of the front-side pad structure 40 and an upper surface of the front-side insulating layer structure 20 may be co-planar. For example, an upper surface of the second front-side pad portion 47 of the front-side pad structure 40, an upper end portion of the front-side pad liner layer 22 of the front-side insulating layer structure 20 and an upper surface of the front-side bonding insulating layer 23 may be co-planar.

The first front-side pad UBM portion 42, the second front-side pad UBM portion 43, and the third front-side pad UBM portion 44 of the front-side pad structure 40 may include a same metal to be unified in one body. That is, interfaces between the first front-side pad UBM portion 42 and the second front-side pad UBM portion 43, and between the second front-side pad UBM portion 43 and the third front-side pad UBM portion 44 might not exist. In addition, the first front-side pad portion 46, the second front-side pad portion 47, and the third front-side pad portion 48 of the front-side pad structure 40 may be include ae same material to be unified. That is, interfaces between the first front-side pad portion 46 and the second front-side pad portion 47, and between the first front-side pad portion 46 and the third front-side pad portion 48 might not exist.

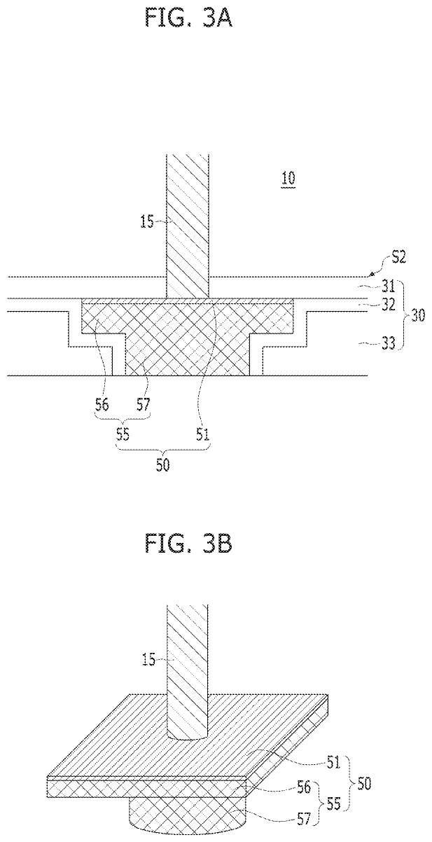

FIG. 3A is an enlarged view of a region B of FIG. 1, and FIG. 3B is a perspective view of the region B. Referring to FIGS. 3A and 3B, the back-side insulating layer structure 30 of the semiconductor die 100A may include a back-side passivation layer 31, a back-side pad liner layer 32, and a back-side bonding insulating layer 33, and the back-side pad structure 50 of the semiconductor die 100A may include a back-side pad UBM layer 51 and a back-side pad pattern 55.

The back-side passivation layer 31 may be disposed flat under the back-side S2 of the body 10 and may expose a lower end portion of the through-via 15. The back-side passivation layer 31 may include at least one of a silicon nitride-based insulating layer, a silicon carbon nitride-based insulating layer, or a silicon oxide-based insulating layer.

The back-side pad UBM layer 51 may be thin and conformally disposed under a lower surface of the back-side passivation layer 31 and a lower end portion of the through-via 15. The back-side pad UBM layer 51 may include a seed metal layer such as copper or titanium for a plating process. The back-side pad UBM layer 51 may have a plate shape in a bottom view. In an embodiment, the back-side pad UBM layer 51 may have a disk shape in the bottom view.

The back-side pad pattern 55 may be disposed under a lower surface of the back-side pad UBM layer 51. The back-side pad pattern 55 may include a first back-side pad portion 56 and a second back-side pad portion 57. The first back-side pad portion 56 may be disposed under the lower surface of the back-side pad UBM layer 51 to have a plate shape in the bottom view. For example, the first back-side pad portion 56 may have a polygonal mesa shape. That is, the first back-side pad portion 56 may have a flat lower surface and a vertical side surface. The first back-side pad portion 56 may have a circular shape or a polygonal shape in the bottom view. As shown in the drawing, it is illustrated that the first back-side pad portion 56 has a rectangular shape in the bottom view. The second back-side pad portion 57 may be disposed under the lower surface of the first back-side pad portion 56 to have a pillar shape or a stair shape protruding downward. That is, the second back-side pad portion 57 may have a mesa shape having a flat lower surface and a vertical side surface. The first back-side pad portion 56 and the second back-side pad portion 57 may form a staircase shape. In the bottom view, the second back-side pad portion 57 may have a circular shape or a polygonal shape. In the embodiment, it is illustrated that the second back-side pad portion 57 has a circular shape in the bottom view.

The back-side pad liner layer 32 may conformally surround side surfaces and lower surfaces of the first back-side pad portion 56 and side surfaces of the second back-side pad portion 57. The back-side pad liner layer 32 may also surround side surfaces of the back-side pad UBM layer 51. The back-side pad liner layer 32 may include an insulating barrier layer such as a silicon nitride layer. For example, the back-side pad liner layer 32 may include at least one of a silicon nitride layer, a silicon carbon nitride layer, a silicon oxy-nitride layer, and other silicon nitride-based layers. The back-side pad liner layer 32 may extend onto a lower surface of the back-side passivation layer 31. In a side view, the back-side pad liner layer 42 may have a staircase shape.

The back-side bonding insulating layer 33 may be disposed under the lower surface of the back-side pad liner layer 32 to surround side surfaces of the back-side pad structure 50. For example, the back-side bonding insulating layer 33 may fill spaces between the back-side pad structures 50. The back-side bonding insulating layer 33 may include at least one of a silicon oxide layer, a silicon nitride layer, a silicon carbon nitride layer, and other insulating layers including silicon, oxygen, and nitrogen.

A lower surface of the back-side insulating layer structure 30 and a lower surface of the back-side pad structure 50 may be co-planar. Specifically, the lower surface of the second back-side pad portion 57 of the back-side pad structure 50, a lower end portion of the back-side pad liner layer 32 of the back-side insulating layer structure 30, and the lower surface of the back-side bonding insulating layer 33 may be co-planar.

The first back-side pad portion 56 and the second back-side pad portion 57 of the back-side pad structure 50 may include a same metal to be unified in one body. That is, an interface between the first back-side pad portion 56 and the second back-side pad portion 57 might not exist.

Because the front-side pad structure 40 according to the embodiment of the disclosure includes the first front-side pad portion 46 and the second front-side pad portion 47, a surface area and volume of the front-side pad structure 40 can be increased. Because the back-side pad structure 50 according to the embodiment of the disclosure includes the first back-side pad portion 56 and the second back-side pad portion 57, a surface area and volume of the back-side pad structure 50 can be increased. Accordingly, the front-side pad structure 40 and the back-side pad structure 50 according to the embodiment may have improved heat dissipation efficiency, and bonding stability.

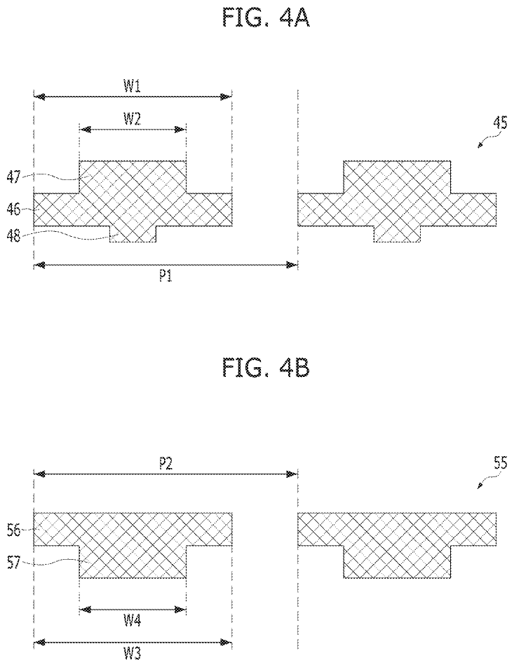

FIGS. 4A and 4B are side views comparing sizes of the front-side pad patterns 45 and the back-side pad patterns 55 according to embodiments of the present disclosure. Referring to FIG. 4A, the front-side pad patterns 45 according to the embodiment of the present disclosure may be arranged with a first horizontal pitch P1. The first front-side pad portion 46 of the front-side pad pattern 45 may have a first horizontal width W1. The second front-side pad portion 47 of the front-side pad pattern 45 may have a second horizontal width W2. The first horizontal width W1 may be set within a range of 60% to 90% of the first horizontal pitch P1. When the first horizontal width W1 is greater than 90% of the first horizontal pitch P1, signal delays or signal errors may occur due to parasitic capacitance or coupling noise between the front-side pad patterns 45. When the first horizontal width W1 is smaller than 60% of the first horizontal pitch P1, the front-side pad pattern 45 might not have a sufficient heat dissipation efficiency and may be difficult to perform a sufficient copper atom source for stable copper-to-copper bonding. The second horizontal width W2 can be set within a range of 20% to 60% of the first horizontal pitch P1. When the second horizontal width W2 is greater than 60% of the first horizontal pitch P1, contact areas of the bonding insulating layers 23 and 33 can be narrowed, and thus bonding stability may be degraded. When the second horizontal width W2 is smaller than 20% of the first horizontal pitch P1, a contact area between the second front-side pad portion 47 and the second back-side pad portion 57 may be narrowed, and thus contact resistance may be increased. To facilitate understanding of the technical concepts of the disclosure, the front-side pad UBM layer 41 and the back-side pad UBM layer 51 and other components are omitted.

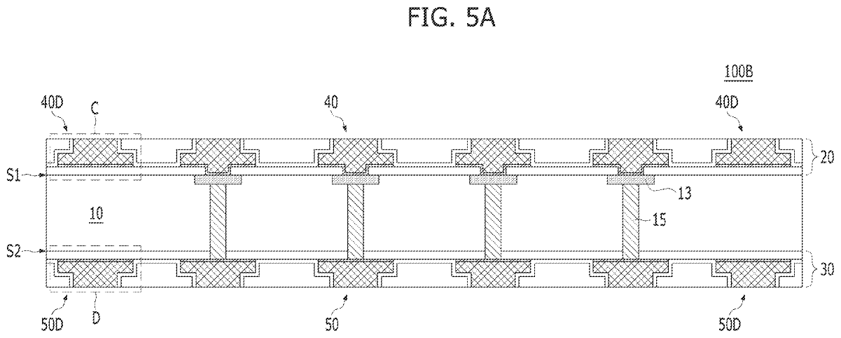

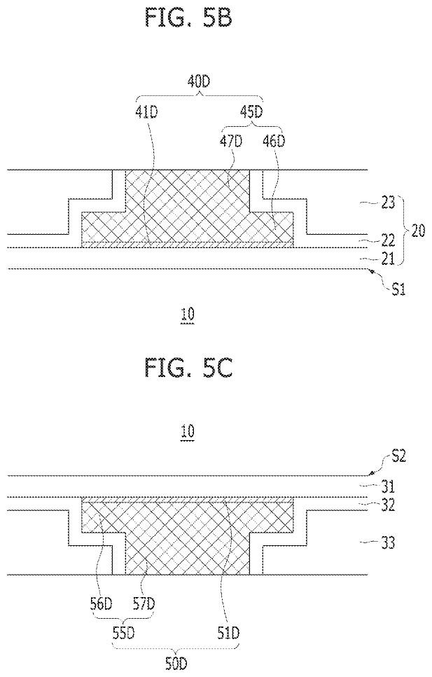

FIG. 5A is a side cross-sectional view illustrating a semiconductor die 100B according to an embodiment of the present disclosure, FIG. 5B is an enlarged view of a region C of FIG. 5A, and FIG. 5C is an enlarged view of a region D of FIG. 5A. Referring to FIGS. 5A to 5C, the semiconductor die 100B may include a body 10 having a front-side S1 and a back-side S2, a front-side insulating layer structure 20 and a front-side pad structures 40 and 40D on the front-side S1 of the body 10, a back-side insulating layer structure 30 and a back-side pad structures 50 and 50D under the back-side S2 of the body 10, and a top metal pattern 13 and a through-via 15 disposed in the body 10.

The front-side insulating layer structure 20 may include a front-side passivation layer 21, a front-side pad liner layer 22, and a front-side bonding insulating layer 23. The back-side insulating layer structure 30 may include a back-side passivation layer 31, a back-side pad liner layer 32, and a back-side bonding insulating layer 33.

The front-side pad structures 40 and 40D may include a front-side pad structure 40 and a dummy front-side pad structure 40D. The back-side pad structures 50 and 50D may include a back-side pad structure 50 and a dummy back-side pad structure 40D.

The dummy front-side pad structure 40D may have a dummy front-side pad UBM layer 41D and a dummy front-side pad pattern 45D. The dummy front-side pad UBM layer 41D may be disposed thin on the front-side passivation layer 21. The dummy front-side pad UBM layer 41D may include a seed metal layer such as a copper layer or a titanium layer. The dummy front-side pad UBM layer 41D may have a plate shape. In an embodiment, the dummy front-side pad UBM layer 41D may have a disk shape in the top view. The dummy front-side pad pattern 45D may include a first dummy front-side pad portion 46D disposed on the dummy front-side pad UBM layer 41D and a second dummy pad portion 47D disposed on the first dummy front-side pad portion 46D. The first dummy front-side pad portion 46D may have the same structure as the first front-side pad portion 46 or the first back-side pad portion 56. The second dummy front-side pad portion 47D may have the same structure as the second front-side pad portion 47 or the second back-side pad portion 57. The dummy front-side pad structure 40D might not be vertically aligned with any of the top metal patterns 13 and the through-vias 15. In an embodiment, the dummy front-side pad structure 40D might not be electrically connected to any of the top metal patterns 13 and the through-vias 15.

The dummy back-side pad structure 50 may have a dummy back-side pad UBM layer 51D and a dummy back-side pad pattern 55D. The dummy back-side pad UBM layer 51D may be disposed thin under the back-side passivation layer 31. The dummy back-side pad UBM layer 51D may include a seed metal layer such as a copper layer or a titanium layer. The dummy back-side pad pattern 55D may include a first dummy back-side pad portion 56D disposed under a lower surface of the dummy back-side pad UBM layer 51D and a second dummy back-side pad portion 57D disposed under a lower surface of the first dummy back-side pad portion 56D. The first dummy back-side pad portion 56D may have the same structure as the first back-side pad portion 56. The second dummy back-side pad portion 57D may have the same structure as the second back-side pad portion 57. The dummy back-side pad structure 50D might not be vertically aligned with any of the top metal patterns 13 and the through-vias 15. In an embodiment, the dummy back-side pad structure 50D might not be electrically connected to any of the top metal patterns 13 and the through-vias 15.

The front-side pad structure 40 may be electrically connected to the back-side pad structure 50 through the top metal pattern 13 and the through-via 15 vertically aligned with the front-side pad structure 40. The dummy front-side pad structure 40D and the dummy back-side pad structure 50D might not be electrically connected to other conductive components.

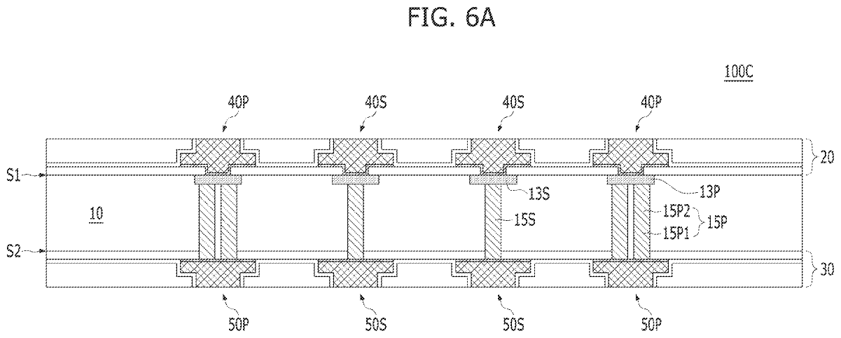

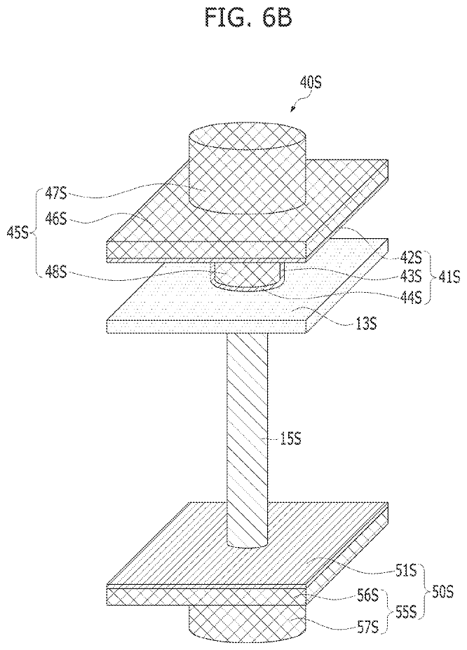

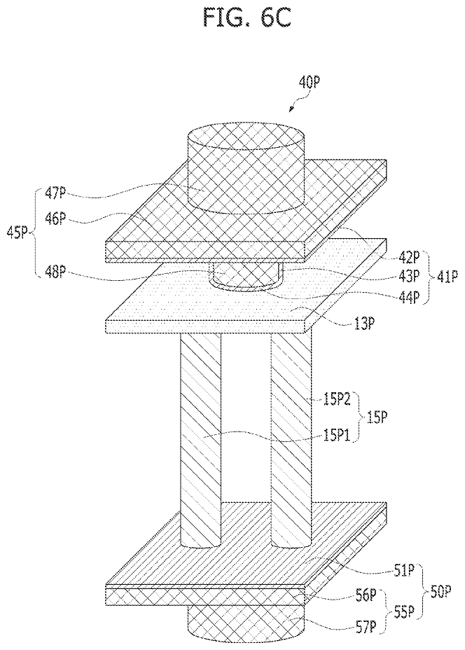

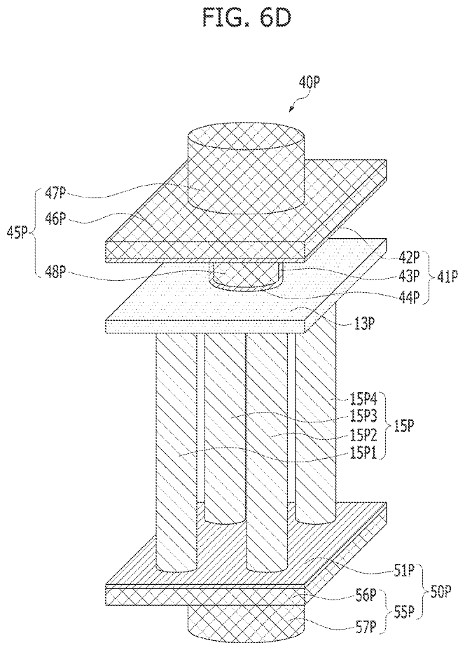

FIG. 6A is a side cross-sectional view illustrating a semiconductor die 100C according to an embodiment of the present disclosure, and FIGS. 6B to 6D are perspective views of front-side pad structures 40S and 40P, back-side pad structures 50S and 50P, top metal patterns 13S and 13P, and through-vias 15S and 15P of FIG. 6A. Referring to FIGS. 6A to 6D, the semiconductor die 100C may include a body 10 having a front-side S1 and a back-side S2, a front-side insulating layer structure 20 and a front-side pad structures 40S and 40P on the front-side S1 of the body 10, a back-side insulating layer structure 30 and a back-side pad structures 50S and 50P under the back-side S2 of the body 10, and top metal patterns 13S and 13P and through-vias 15S and 15P disposed in the body 10.

The front-side pad structures 40S and 40P may include a signal front-side pad structure 40S and a power front-side pad structure 40P. The back-side pad structures 50S and 50P may include a signal back-side pad structure 50S and a power back-side pad structure 50P. The top metal patterns 13S and 13P may include a signal top metal pattern 13S and a power top metal pattern 13P. The through-vias 15S and 15P may include a signal front-side pad structure 40S and a power front-side pad structure 40P.

The signal front-side pad structure 40S, the signal back-side pad structure 50S, the signal top metal pattern 13S, and the signal through-via 15S may transmit a clock signal, a command signal, an address signal, or a data signal. The power front-side pad structure 40P, the power back-side pad structure 50P, the power top metal pattern 13P, and the power through-via 15P may transmit various reference voltages Vrefs such as VDD, VPP, VDDq, VSS, or VSSq.

The elements 13S, 15S, 40S, and 50S for signal transmission may have a single signal transmission path to prevent inconsistency, signal delay, or signal attenuation of signals due to path differences. That is, one signal through-via 15S may electrically connect the signal top metal pattern 15S to the signal back-side pad structure 50S. To stably transmit the reference voltages, the elements 13P, 15P, 40P, and 50P may have dual or double signal transmission paths. For example, the power through-via 15P may include a plurality of unit power through-vias 15P1 to 15P4. That is, the plurality of unit power through-vias 15P1 to 15P4 may electrically and commonly connect the power top metal pattern 13P to the power back-side pad structure 50P. In an embodiment, the signal through-vias 15S and the unit power through-vias 15P1 to 15P2 may each have the same specifications. For example, the signal through-vias 15S and the unit power through-vias 15P1 to 15P4 may have the same material, the same length, and the same width or diameter.

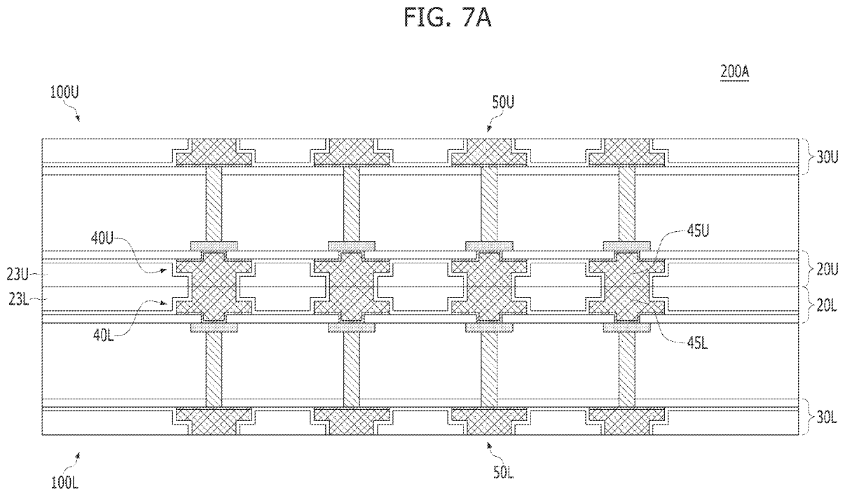

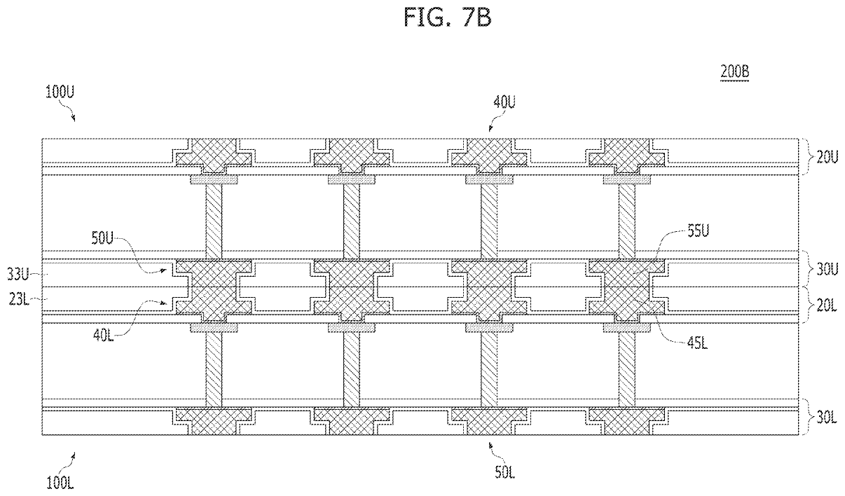

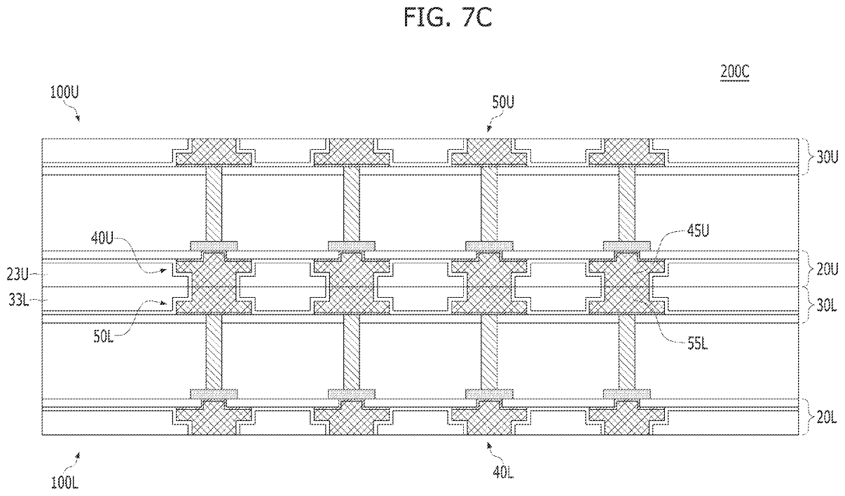

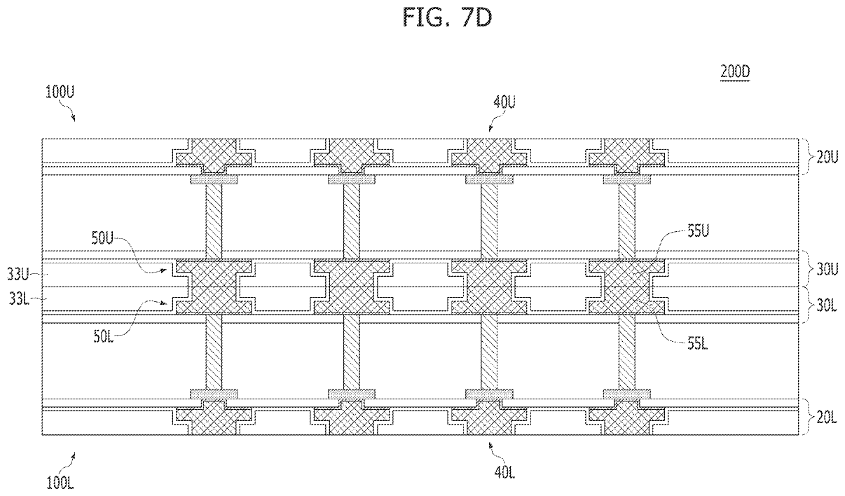

FIGS. 7A to 7D are side cross-sectional views illustrating semiconductor die stack units 200A to 200D according to embodiments of the present disclosure. Referring to FIGS. 7A to 7D, the semiconductor die stack units 200A to 200D may include two stacked semiconductor dies 100L and 100U. That is, each of the semiconductor die stack units 200A to 200D may include a lower semiconductor die 100L and an upper semiconductor die 100U. The upper semiconductor die 100U may be bonded onto the lower semiconductor die 100L in a hybrid bonding method.

Referring to FIG. 7A, the semiconductor die stack unit 200A may include the lower semiconductor die 100L and the upper semiconductor die 100U bonded and stacked in a face-to-face method. For example, the front-side insulating layer structure 20L of the lower semiconductor die 100L and the front-side insulating layer structure 20U of the upper semiconductor die 100U may be in contact with and bonded to each other, and the front-side pad structure 40L of the lower semiconductor die 100L and the front-side pad structure 40U of the upper semiconductor die 100U may be in contact with and bonded to each other. Specifically, the front-side bonding insulating layer 23L of the front-side bonding insulating layer structure 20L of the lower semiconductor die 100L and the front-side bonding insulating layer 23U of the front-side bonding insulating layer structure 20U of the upper semiconductor die 100U may be in directly contact with each other, and the front-side pad pattern 45L of the front-side pad structure 40L of the lower semiconductor die 100L and the front-side pad pattern 45U of the front-side pad structure 40U of the upper semiconductor die 100U may be in contact with each other. The lower semiconductor die 100L may be bonded to the upper semiconductor die 100U in a face-up method, and the upper semiconductor die 100U may be bonded to the lower semiconductor die 100L in a face-down method.

Referring to FIG. 7B, the semiconductor die stack unit 200B may include the lower semiconductor die 100L and the upper semiconductor die 100U bonded and stacked in a face-to-back method. For example, the front-side insulating layer structure 20L of the lower semiconductor die 100L and the back-side insulating layer structure 30U of the upper semiconductor die 100U may be in contact with and bonded to each other, and the front-side pad structure 40L of the lower semiconductor die 100L and the back-side pad structure 50U of the upper semiconductor die 100U may be in contact with and bonded to each other. Specifically, the front-side bonding insulating layer 23L of the front-side bonding insulating layer structure 20L of the lower semiconductor die 100L and the back-side bonding insulating layer 33U of the back-side bonding insulating layer structure 30U of the upper semiconductor die 100U may be in directly contact with each other, and the front-side pad pattern 45L of the front-side pad structure 40L of the lower semiconductor die 100L and the back-side pad pattern 55U of the back-side pad structure 50U of the upper semiconductor die 100U may be in contact with each other. Both the lower semiconductor die 100L and the upper semiconductor die 100U may be stacked and bonded in a face-up method.

Referring to FIG. 7C, the semiconductor die stack unit 200C may include the lower semiconductor die 100L and the upper semiconductor die 100U bonded and stacked in a back-to-face method. For example, the back-side insulating layer structure 30L of the lower semiconductor die 100L and the front-side insulating layer structure 20U of the upper semiconductor die 100U may be in contact with and bonded to each other, and the back-side pad structure 50L of the lower semiconductor die 100L and the front-side pad structure 40U of the upper semiconductor die 100U may be in contact with and bonded to each other. Specifically, the back-side bonding insulating layer 33L of the back-side bonding insulating layer structure 30L of the lower semiconductor die 100L and the front-side bonding insulating layer 23U of the front-side bonding insulating layer structure 20U of the upper semiconductor die 100U may be in directly contact with and bonded to each other, and the back-side pad pattern 55L of the back-side pad structure 50L of the lower semiconductor die 100L and the front-side pad pattern 45U of the front-side pad structure 40U of the upper semiconductor die 100U may be in contact with and bonded to each other. Both the lower semiconductor die 100L and the upper semiconductor die 100U may be bonded in a face-down method.

Referring to FIG. 7D, the semiconductor die stack unit 200D according to an embodiment of the present disclosure may include the lower semiconductor die 100L and the upper semiconductor die 100U bonded and stacked in a back-to-back method. For example, the back-side insulating layer structure 30L of the lower semiconductor die 100L and the back-side insulating layer structure 30U of the upper semiconductor die 100U may be in contact with and bonded to each other, and the back-side pad structure 50L of the lower semiconductor die 100L and the back-side pad structure 50U of the upper semiconductor die 100U may be in contact with and bonded to each other. Specifically, the back-side bonding insulating layer 33L of the back-side bonding insulating layer structure 30L of the lower semiconductor die 100L and the back-side bonding insulating layer 33U of the back-side bonding insulating layer structure 30U of the upper semiconductor die 100U may be in directly contact with each other, and the back-side pad pattern 55L of the back-side pad structure 50L of the lower semiconductor die 100L and the back-side pad pattern 55U of the back-side bonding insulating layer structure 50U of the upper semiconductor die 100U may be in directly contact with each other. The lower semiconductor die 100L may be stacked and bonded in a face-down method, and the upper semiconductor die 100U may be stacked and bonded by a face-up method.

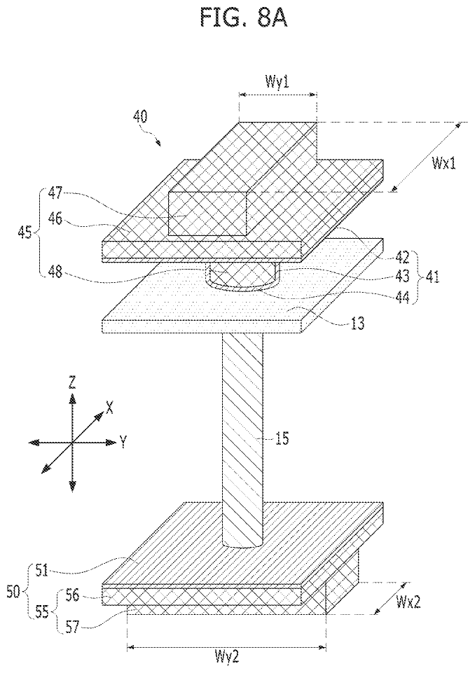

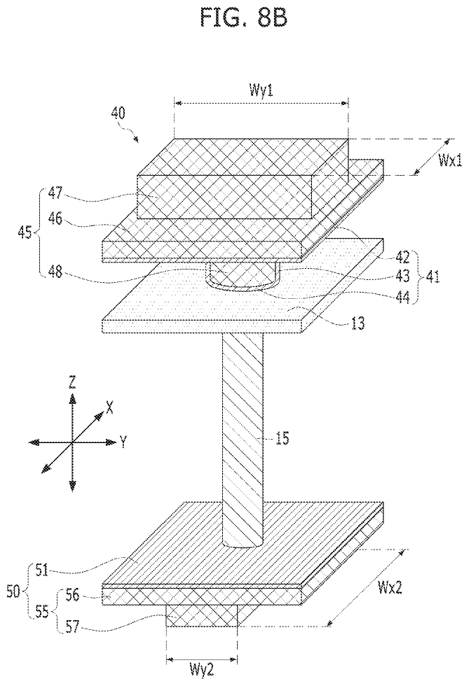

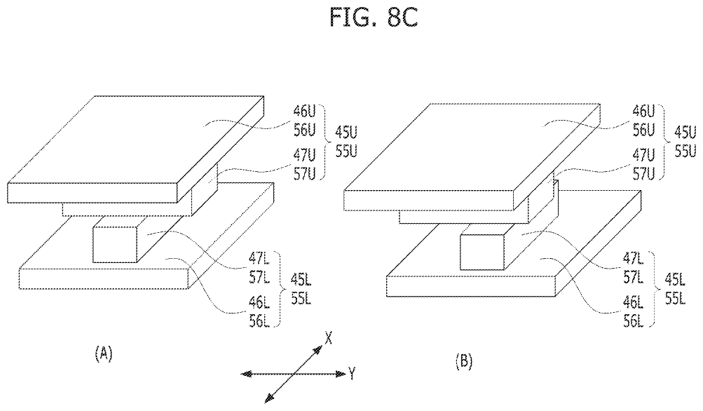

FIGS. 8A and 8B are perspective views illustrating a front-side pad structure 40 and a back-side pad structure 50 according to embodiments of the present disclosure. Referring to FIGS. 8A and 8B, the second front-side pad portion 47 of the front-side pad pattern 45 of the front-side pad structure 40 may have an elongated bar shape in a first horizontal direction X or a second horizontal direction Y, and the second back-side pad portion 57 of the back-side pad pattern 55 of the back-side pad structure 50 may have the second horizontal direction Y or the first horizontal direction X. For example, the second front-side pad portion 47 and the second back-side pad portion 57 may extent crossing with each other.

Referring to FIG. 8A, a width Wx1 of the second front-side pad portion 47 may be greater than a width Wx2 of the second back-side pad portion 57 in the first horizontal direction X, and a width Wy1 of the second front-side pad portion 47 may be smaller than a width Wy2 of the second back-side pad portion 57 in the second horizontal direction Y. (Wx1>Wx2, Wy1<Wy2)

Referring to FIG. 8B, the width Wx1 of the second front-side pad portion 47 may be smaller than the width Wx2 of the second back-side pad portion 57 in the first horizontal direction X, and the width Wy1 of the second front-side pad portion 47 may be greater than the width Wy2 the second back-side pad portion 57 in the second horizontal direction Y. (Wx1<Wx2, Wy1>Wy2)

The through-via 15 may extend in a vertical direction Z. The first horizontal direction X, the second horizontal direction Y, and the vertical direction Z may be perpendicular to each other.

FIG. 8C is a simplified perspective view illustrating shapes in which the front-side pad patterns 45U and 45L and the back-side pad patterns 55U and 55L are aligned with and bonded to each other. Referring to (A) of FIG. 8C, the upper pad patterns 45U and 55U and the lower pad patterns 45L and 55L may be good aligned with each other. Referring to (B) of FIG. 8C, the upper pad patterns 45U and 55U and the lower pad patterns 45L and 55L may be offset aligned with each other. The upper pad patterns 45U and 55U may include first upper pad patterns 46U and 56U and second upper pad patterns 47U and 57U, and the lower pad patterns 45L and 55L may include first lower pad patterns 46L and 56L and second lower pad patterns 47L and 57L. Each of the second upper pad patterns 47U and 57U and the second lower pad patterns 47L and 57L may have a bar shape elongated in crossing directions perpendicular to each other. Accordingly, the second upper pad patterns 47U and 57U and the second lower pad patterns 47L and 57L may be bonded to have the same contact areas regardless of good alignment and offset alignment.

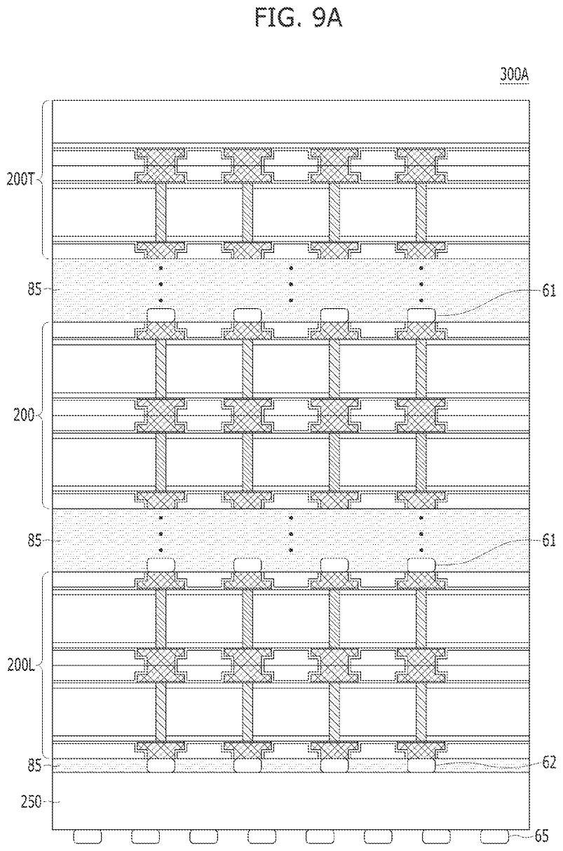

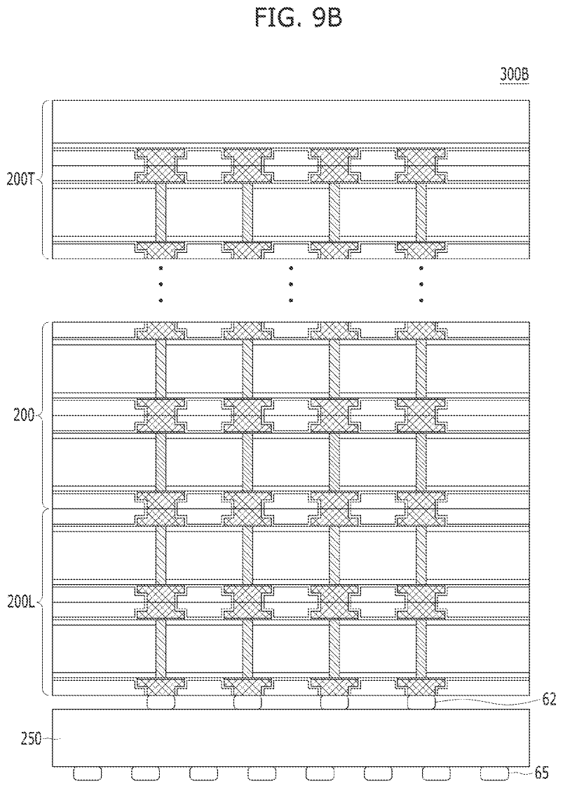

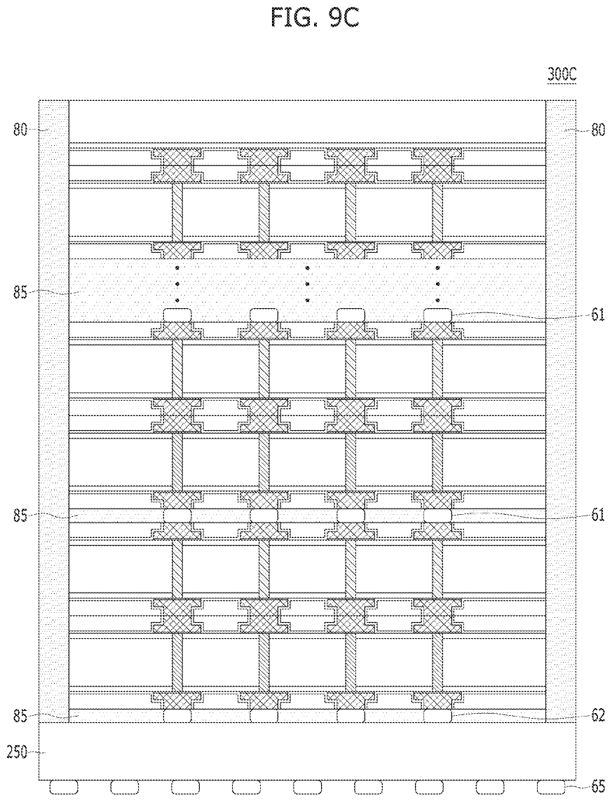

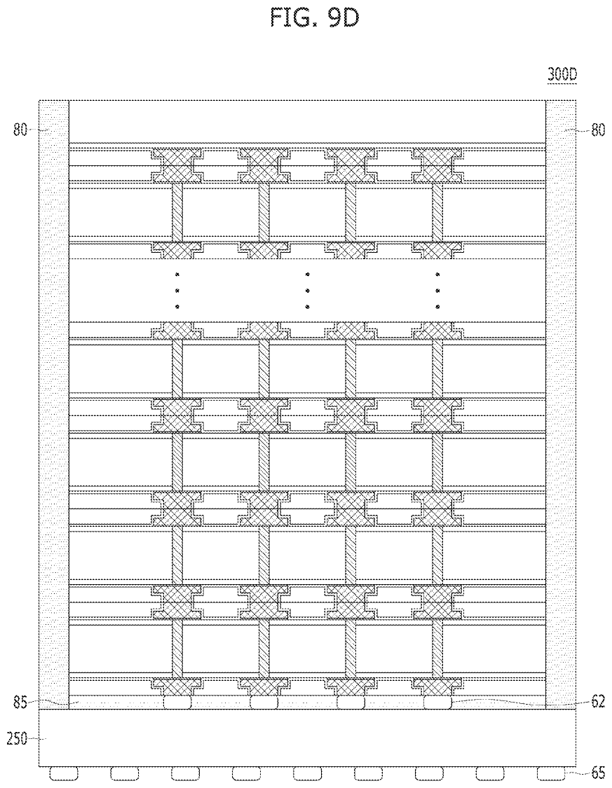

FIGS. 9A to 9D are side cross-sectional views illustrating semiconductor die stack structures 300A to 300D according to embodiments of the present disclosure. Referring to FIGS. 9A to 9D, the semiconductor die stack structures 300A-300D may include a plurality of semiconductor die stack units 200, 200L, and 200T stacked on the base die 250. The plurality of semiconductor die stack units 200, 200L, and 200T may include a lowermost semiconductor die stack unit 200L, a plurality of intermediate semiconductor die stack units 200, and a top semiconductor die stack unit 200T.

Referring to FIG. 9A, the semiconductor die stack structure 300A may include the plurality of semiconductor die stack units 200, 200L, and 200T stacked on the base die 250. The second pad portions 47 and 57 of the pad patterns 45 and 55 of the pad structures 40 and 50 of each of the semiconductor die stack units 200, 200L, and 200T may be physically bonded and electrically connected to each other through inter-unit connectors 61. The base die 250 and the lowermost semiconductor die stack unit 200L may be bonded and connected to each other through inter-stack connectors 62. The base die 250 may further include base die connectors 65 to be connected to an external interposer. The inter-unit connectors 61, the inter-stack connectors 62, and the base die connectors 65 may include solder balls.

Referring to FIG. 9B, the semiconductor die stack structure 300B may include the plurality of semiconductor die stack units 200, 200L, and 200T stacked on the base die 250 in a hybrid bonding method. For example, the second pad portions 47 and 57 of the pad patterns 45 and 55 of the pad structures 40 and 50 of each of the semiconductor die stack units 200, 200L, and 200T may be in directly contact with each other to be bonded, and the bonding insulating layers 23 and 33 of each of the semiconductor die stack units 200, 200L, and 200T may be in directly contact with each other to be bonded. The base die 250 and the lowermost semiconductor die stack unit 200L may be bonded to each other through the inter-stack connectors 62.

Referring to FIGS. 9C and 9D, the semiconductor die stack structures 300C and 300D may further include a heat dissipation molding layer 80 disposed on side surfaces of the stacked semiconductor die stack units 200, 200L, and 200T. The heat dissipation molding layer 80 may be in contact with an upper surface of the base die 250. The heat dissipation molding layer 80 may include an epoxy resin and aluminum nitride fillers. The aluminum nitride fillers have better thermal conductivity than silica fillers and alumina fillers. Accordingly, the heat dissipation molding layer 80 may dissipate heat generated from the semiconductor die stack units 200, 200L, and 200T to outside better than a molding layer including silica or alumina. In an embodiment, the heat dissipation molding layer 80 may further include carbon (C). Spaces between the inter-unit connectors 61 and between the base die connectors 65 may be filled by an underfill material layer 85. The underfill material layer 85 may include an insulating material including a thermosetting resin such as an epoxy resin.

Each of the semiconductor die stack units 200, 200L, and 200T may be any one of the semiconductor die stack units 200A to 200D shown in FIGS. 7A to 7D. For example, each of the semiconductor die stack units 200, 200L, and 200T may include two semiconductor dies 100U and 100L stacked and bonded to each other. Accordingly, the semiconductor die stack structures 300A and 300B may be formed by stacking the plurality of semiconductor die stack units 200, 200L, and 200T including two semiconductor dies 100U and 100L.

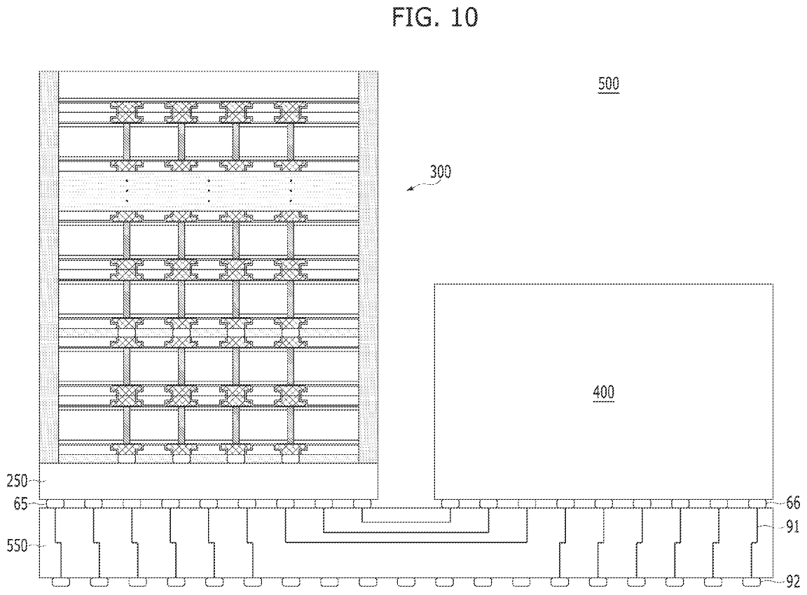

FIG. 10 is a side cross-sectional view illustrating a high-bandwidth memory 500 according to an embodiment of the present disclosure. Referring to FIG. 10, the high-bandwidth memory 500 may include the semiconductor die stack structure 300 and a processing unit 400 disposed on an interposer 550. The interposer 550 may include a printed circuit board (PCB) or a silicon wafer. The semiconductor die stack structure 300 may be one of the semiconductor die stack structures 300A to 300D shown in FIGS. 9A to 9D. The interposer 550 may include interposer interconnections 91. The semiconductor die stack 300 and the processing unit 400 may be electrically coupled through the base die connectors 65, the interposer interconnections 91, and the processing unit connector 66. The interposer 550 may be coupled to an external system through the interposer connectors 92.

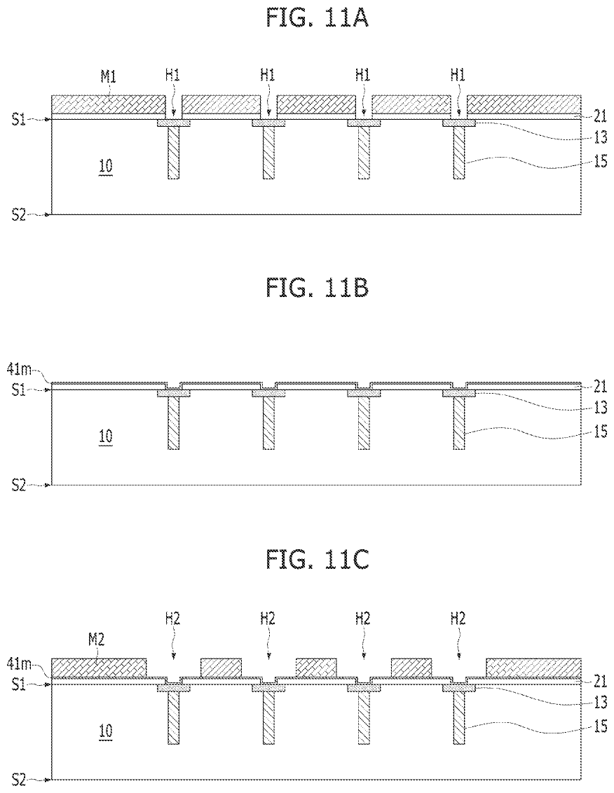

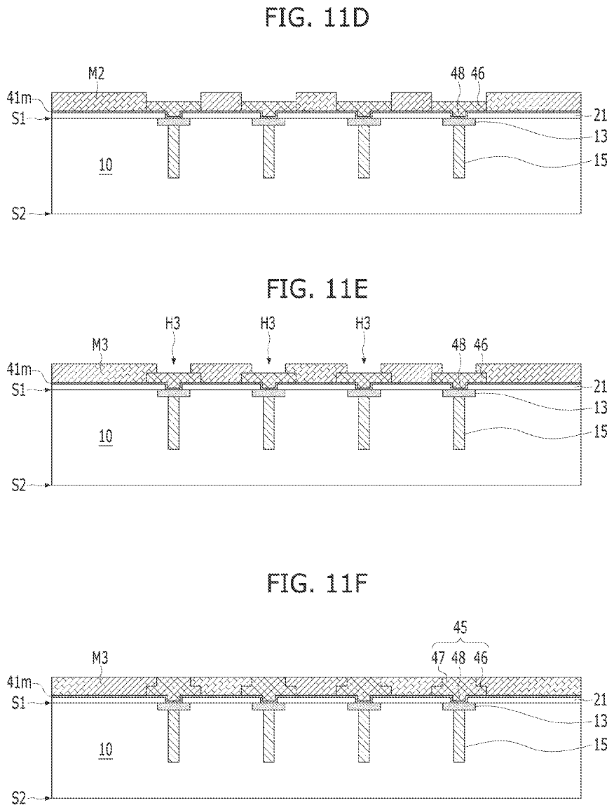

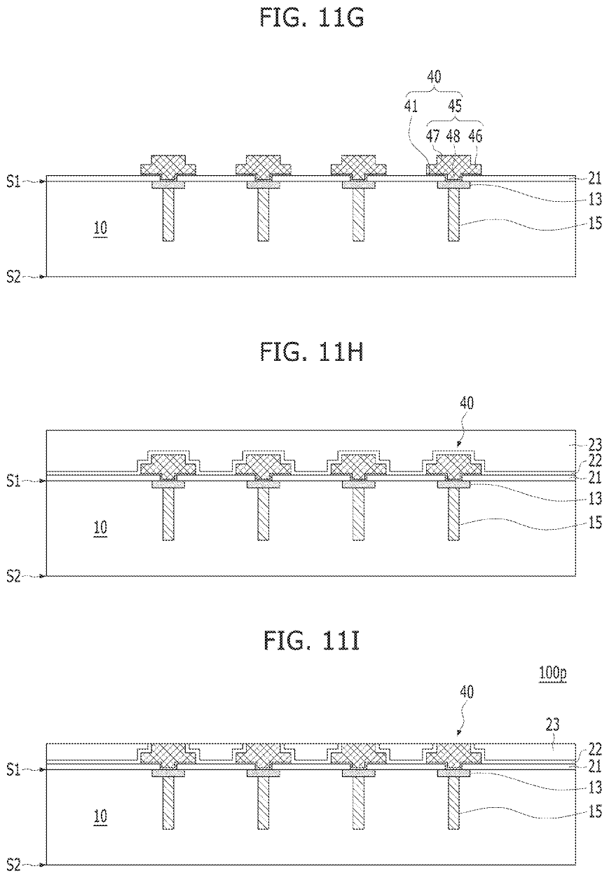

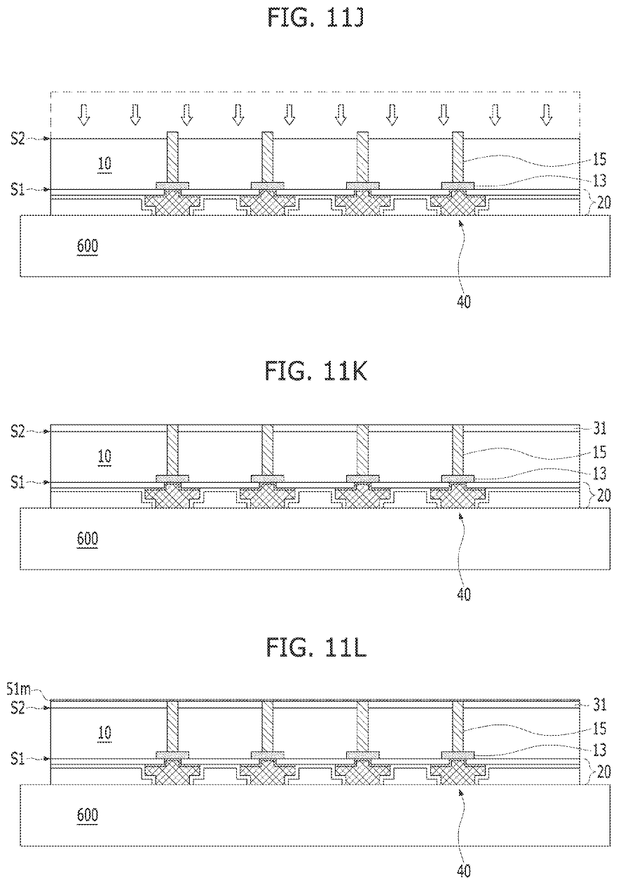

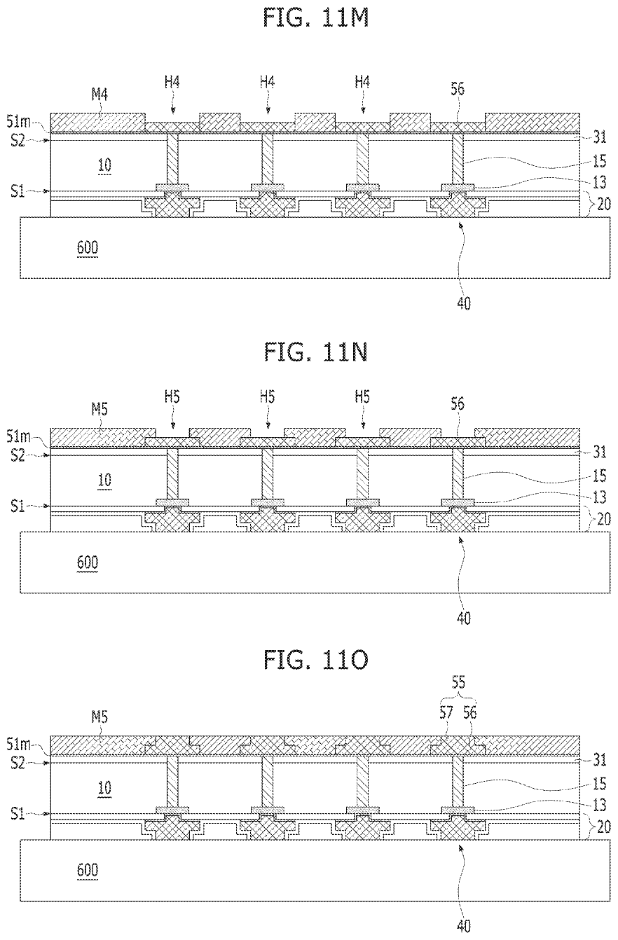

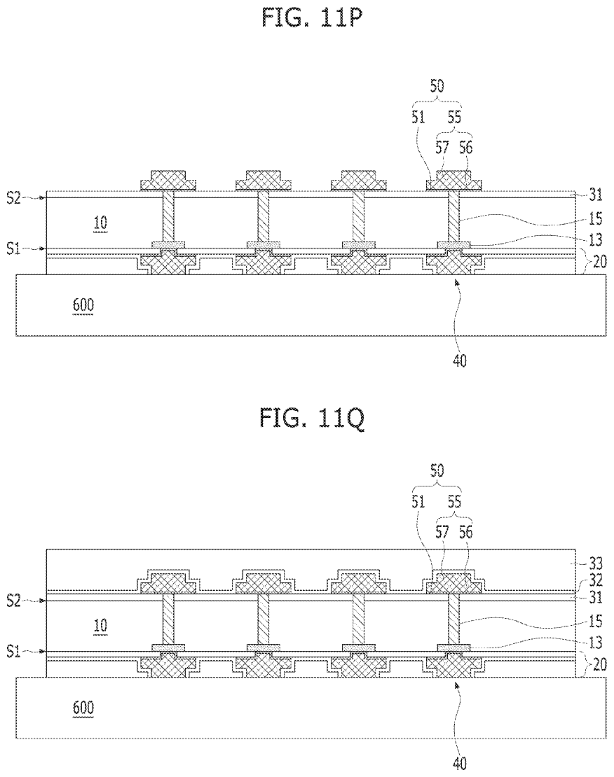

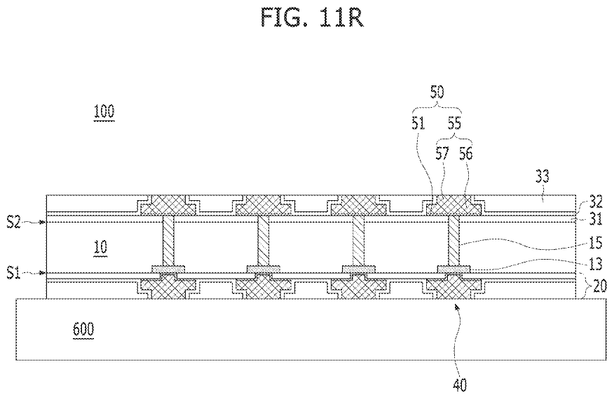

FIGS. 11A to 11R are side cross-sectional views illustrating a method of manufacturing a semiconductor die according to an embodiment of the present disclosure. Referring to FIG. 11A, the method may include preparing a body 10 including a top metal pattern 13 and a through-via 15, forming a front-side passivation layer 21 on a front-side S1 of the body 10, forming a first mask pattern M1 on the front-side passivation layer 21, and forming a front-side lower hole H partially exposing an upper side of the top metal pattern by performing an etching process using the first mask pattern M1 as an etch mask to remove a portion of the front-side passivation layer 21. The front-side lower hole H1 may be vertically aligned with the top metal pattern 13 and the through-via 15.

The body 10 may include a silicon wafer, transistors and metal interconnections formed on the silicon wafer, and a plurality of insulating layers surrounding the transistors and the metal interconnections. The front-side S1 of the body 10 may be an active surface, for example, a top surface of an insulating layer covering a circuit element such as the transistors formed on an upper surface of the silicon wafer. A back-side S2 of the body 10 may be a lower surface of the silicon wafer on which any circuit elements are not formed.

The top metal pattern 13 may be disposed in the body 10 to electrically connect the front-side pad structure 40 and electrical circuits in the body 10. The top metal pattern 13 may be an uppermost metal layer of the semiconductor circuits. The top metal pattern 13 may include a metal such as aluminum, tungsten, nickel, copper, or other metals. A lower surface of the top metal pattern 13 may be in contact with an upper end portion of the through-via 15.

The through-via 15 may vertically pass through the body 10 to be aligned with the top metal pattern 13, and may electrically connect the top metal pattern 13 to the back-side pad structure 50. The through-via 15 may include copper (Cu). An insulating via liner (not shown) may be further formed on side surfaces of the through-via 15. The insulating via liner may electrically insulate the through-via 15 from the body 10. A lower end portion of the through-via 15 may be located in the body 10.

The front-side passivation layer 21 may be formed flat on the front-side S1 of the body 10 and may expose a portion of the upper surface of the top metal pattern 13. The front-side passivation layer 21 may include at least one of a silicon nitride-based insulating layer, a silicon carbon nitride-based insulating layer, or a silicon oxide-based insulating layer.

The first mask pattern M1 may be formed by performing a photolithography process. For example, the first mask pattern M1 may include a photoresist.

Referring to FIG. 11B, the method may further include performing a strip process to remove the first mask pattern M1 and performing a physical vapor deposition (PVD) process such as a sputtering process to conformally form a front-side pad UBM material layer 41m on the upper surface of the front-side passivation layer 21 and the exposed upper surface of the top metal pattern 13. The front-side pad UBM material layer 41m may include at least one of titanium (Ti), copper (Cu), and nickel (Ni). The front-side pad UBM material layer 41m may also be formed on sidewalls of the front-side passivation layer 21 defining the front-side lower hole H1.

Referring to FIG. 11C, the method may further include forming a second mask pattern M2 having a front-side intermediate hole H2 by performing a photolithography process. The second mask pattern M2 may also include a photoresist. The front-side intermediate hole H2 may also be vertically aligned with the top metal pattern 13 and the through-via 15.

Referring to FIG. 11D, the method may further include forming a front-side lower pad portion 48 and a front-side intermediate pad portion 46 partially filling the front-side lower hole H1 and the front-side intermediate hole H2 by performing a plating process. The front-side lower pad portion 48 may fill the front-side lower hole H1, and the front-side intermediate pad portion 46 may fill the front-side intermediate hole H2. The front-side lower pad portion 48 and the front-side intermediate pad portion 46 may include copper (Cu) or nickel (Ni).

Referring to FIG. 11E, the method may further include removing the second mask pattern M2 by performing a strip process, and forming a third mask pattern M3 having a front-side upper hole H3 by performing a photolithography process. A width of the front-side upper hole H3 may be narrower than a width of the front-side intermediate hole H2. Accordingly, the third mask pattern M3 may partially cover surfaces of the front-side intermediate pad portion 46 closer to edges of the front-side intermediate pad portion 46 and expose central surfaces of the front-side intermediate pad portion 46.

Referring to FIG. 11F, the method may further include forming a front-side upper pad portion 47 filling the front-side upper hole H3 performing a plating process. A front-side pad pattern 45 may be formed. The front-side pad pattern 45 may include a plate-shaped front-side intermediate pad portion 46, a front-side upper pad portion 47 protruding upward, and a front-side lower pad portion 48 protruding downward.

Referring to FIG. 11G, the method may further include removing the third mask pattern M3 by performing a strip process, and partially removing the exposed front-side pad UBM material layer 41m by performing an etching process to form a front-side pad UBM layer 41 remaining only under a lower surface of the front-side pad pattern 45. Referring again to FIGS. 1, 2A, and 2B, the front-side pad UBM layer 41 may include a first front-side pad UBM portion 42, a second front-side pad UBM portion 43, and a third front-side pad UBM portion 44. A front-side pad structure 40 including the front-side pad UBM layer 41 and the front-side pad pattern 45 may be formed.

Referring to FIG. 11H, the method may further include conformally forming a front-side pad liner layer 22 covering the front-side passivation layer 21 and the front-side pad structure 40, and forming a front-side bonding insulating layer 23 on the front-side pad liner layer 22 by performing deposition processes. The front-side pad liner layer 22 may include a barrier insulating layer such as a silicon nitride layer. The front-side bonding insulating layer 23 may include at least one of a silicon oxide layer, a silicon nitride layer, a silicon carbon nitride layer, and other insulating layers including silicon, oxygen, and nitrogen.

Referring to FIG. 11I, the method may include co-planarizing an upper surface of the front-side pad structure 40, an upper surface of the front-side pad liner layer 22, and an upper surface of the front-side bonding insulating layer 23 by performing a planarization process such as chemical mechanical polishing (CMP). A front-side insulating layer structure 20 including the front-side passivation layer 21, the front-side pad liner layer 22, and the front-side bonding insulating layer 23 may be formed. That is a preliminary semiconductor die 100p may be formed.

Referring to FIG. 11J, the method may further include reversely mounting the preliminary semiconductor die 100p on a carrier substrate 600 so that the front-side pad structure 40 and the front-side insulating layer structure 20 face downward the carrier substrate 600, and recessing and removing the back-side S2 of the body 10. Recessing and removing the back-side S2 of the body 10 may include performing a grinding process or a CMP process. The end portion of the through-via 15 may protrude upward from the back-side S2 of the body 10.

Referring to FIG. 11K, the method may further include forming a back-side passivation layer 31 under the back-side S2 of the body 10. The end portion of the through-via 15 may be buried in the back-side passivation layer 31 so that the upper surface of the through-via 15 is exposed under the back-side passivation layer 31. Forming the back-side passivation layer 31 may include forming an insulating layer such as a silicon nitride layer by performing a deposition process and a planarization process such as CMP.

Referring to FIG. 11L, the method may further include forming a back-side pad UBM material layer 51m under the back-side passivation layer 31. The back-side pad UBM material layer 51m may be formed by performing a PVD process such as sputtering. The back-side pad UBM material layer 51m may include at least one titanium (Ti), copper (Cu), and nickel (Ni).

Referring to FIG. 11M, the method may further include forming a fourth mask pattern M4 by performing a photolithography process, and forming a first back-side pad portion 56 under the back-side pad UBM material layer 51m by performing a plating process. The fourth mask pattern M4 may include a photoresist. The fourth mask pattern M4 may include a back-side lower hole H4 partially exposing the back-side pad UBM material layer 51m. The first back-side pad portion 56 may partially fill the back-side lower hole H4.

Referring to FIG. 11N, the method may further include removing the fourth mask pattern M4 by performing a strip process and forming a fifth mask pattern M5 by performing a photolithography process. The fifth mask pattern M5 may have a back-side upper hole H5 partially covering surfaces of the first back-side pad portion 56 closer to the edges of the first back-side pad portion 56 and partially exposing central surfaces of the first back-side pad portion 56. A width of the back-side upper hole H5 may be smaller than a width of the back-side lower hole H4.

Referring to FIG. 11O, the method may further include forming a second back-side pad portion 57 by performing a plating process. The second back-side pad portion 57 may fill the back-side upper hole H5. The second back-side pad portion 57 may include copper (Cu) or nickel (Ni). Accordingly, the first back-side pad portion 56 and the second back-side pad portion 57 may include the same metal to be unified in one body. A back-side pad pattern 55 including the first back-side pad portion 56 and the second back-side pad portion 57 may be formed.

Referring to FIG. 11P, the method may further include removing the fifth mask pattern M5 by performing a strip process and removing the exposed back-side pad UBM material layer 51m by performing an etching process to form a back-side pad UBM layer 51 remaining only under the lower surface of the back-side pad pattern 55. Referring again to FIGS. 1, 3A, and 3B, the back-side pad UBM layer 51 may include a first back-side pad UBM portion 52 and a second back-side pad UBM portion 53. A back-side pad structure 50 including the back-side pad UBM layer 51 and the back-side pad pattern 55 may be formed.

Referring to FIG. 11Q, the method may further include conformally forming a back-side pad liner layer 32 covering the back-side passivation layer 31 and the back-side pad structure 50, and forming a back-side bonding insulating layer 33 under the back-side pad liner layer 32 by performing deposition processes. The back-side pad liner layer 32 may include a barrier insulating layer such as a silicon nitride layer. The back-side bonding insulating layer 33 may include at least one of a silicon oxide layer, a silicon nitride layer, a silicon carbon nitride layer, and other insulating s including silicon, oxygen, and nitrogen.

Referring to FIG. 11R, the method may further include co-planarizing an upper surface of the back-side pad structure 50, an upper surface of the back-side pad liner layer 32, and an upper surface of the back-side bonding insulating layer 33 by performing a planarization process such as a CMP process. A back-side insulating layer structure 30 including the back-side passivation layer 31, the back-side pad liner layer 32, and the back-side bonding insulating layer 33 may be formed. Thereafter, the semiconductor die 100A shown in FIG. 1 may be formed by being separated from the carrier substrate 600.

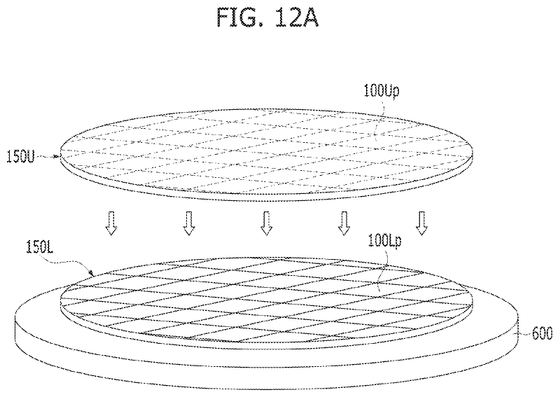

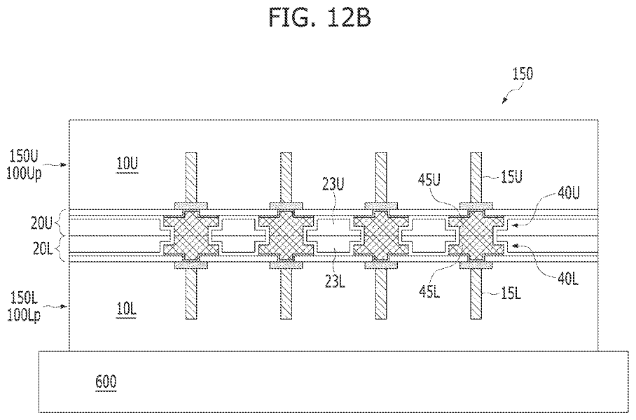

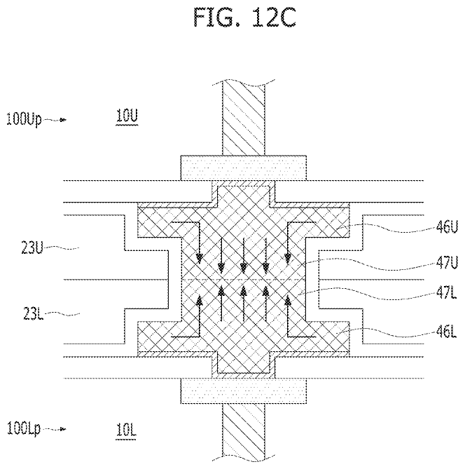

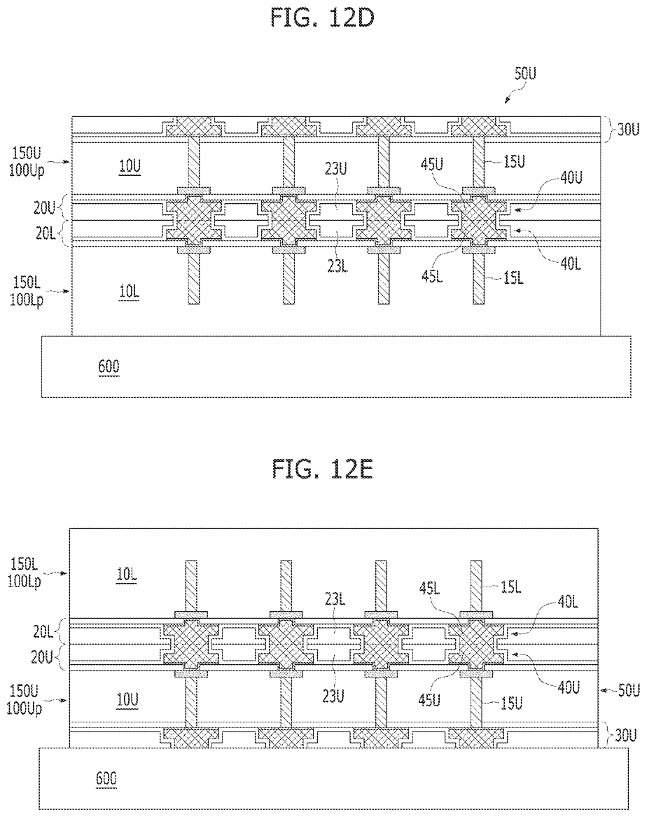

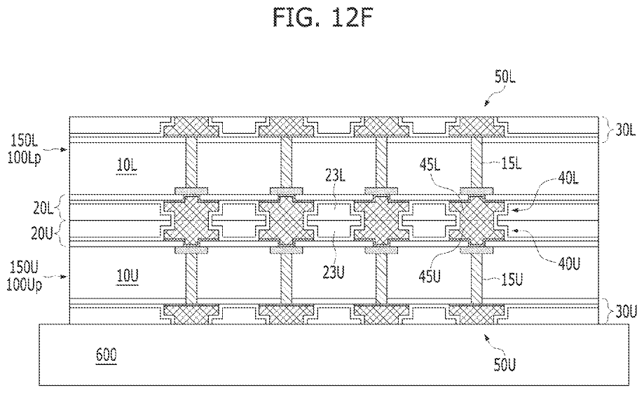

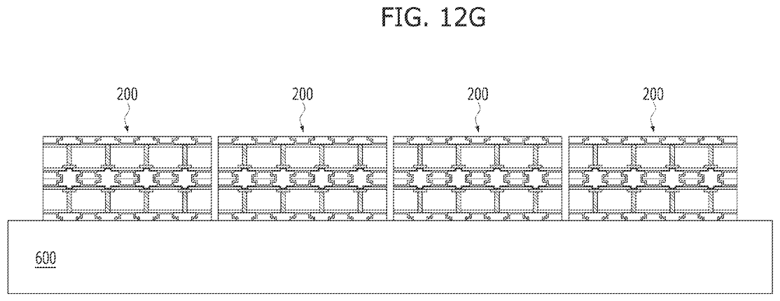

FIGS. 12A to 12G are views illustrating a method of forming a semiconductor die stack unit 200A according to an embodiment of the present disclosure. Referring to FIGS. 12A to 12C, the method of forming the semiconductor die stack unit 200A may include mounting a lower wafer 150L on a carrier substrate 600, and bonding an upper wafer 150U to the lower wafer 150L in a face-to-face method and a wafer-to-wafer bonding method. The lower wafer 150L may include a plurality of preliminary lower semiconductor dies 100Lp, and the upper wafer 150U may include a plurality of preliminary upper semiconductor dies 100Up. That is, the preliminary lower semiconductor dies 100Lp and the preliminary upper semiconductor dies 100Lp may include front-side insulating layer structures 20L and 20U and front-side pad structures 40L and 40U, respectively. The preliminary lower semiconductor dies 100Lp and the preliminary upper semiconductor dies 100Up may include through-vias 15L and 15U having lower end portions positioned embedded in the bodies 10L and 10U, respectively.

The lower second front-side pad portions 45L of the lower front-side pad structures 40L of the preliminary lower semiconductor dies 100Lp of the lower wafer 150L and the upper second front-side pad portions 45U of the upper front-side pad structures 40U of the preliminary upper semiconductor dies 100Up of the upper wafer 150U may be in directly contact with and bonded to each other. The lower front-side bonding insulating layer 23L of the lower front-side insulating layer structure 20L of the preliminary lower semiconductor die 100Lp of the lower wafer 150L and the upper front-side bonding insulating layer 23U of the upper front-side insulating layer structure 20U of the preliminary upper semiconductor die 100Up of the upper wafer 150U may be in directly contact with and bonded to each other.

Referring again to FIG. 12C, in the wafer bonding process, the lower and upper second front-side pad portions 47L and 47U may be expanded to be bonded to each other, and the lower and upper first front-side pad portions 46L and 46U may supply a bonding material source for expansion to the lower and upper second front-side pad portions 47L and 47U, for example, copper Cu. (Refer to Arrows) Because the lower and upper front-side pad structures 40L and 40U include the lower and upper first front-side pad portions 46L and 46U, respectively, each of the lower and upper front-side pad structures 40L and 40U can have an increased volume. Therefore, when the lower and upper first front-side pad portions 46L and 46U are expanded to be bonded to each other, copper atoms can be sufficiently supplied from the lower and upper first front-side pad portions 46L and 46U to the lower and upper second front-side pad portions 47L and 47U. Accordingly, a copper direct bonding process can be physically and stably performed, and an electrical contact resistance of the bonded lower and upper second front-side pad portions 47L and 47U do not be increased. In addition, in the lower and upper front-side pad structures 40L and 40U, a volume of the lower and upper front-side pad portions 46L and 46U buried in the lower and upper front-side bonding insulating layers 23L and 23U are increased, and upper surface areas of the exposed lower and second front-side pad portions 47L and 47U did not be increased. Accordingly, electrical performance of the lower and upper front-side pad structures 40L and 40U can be maintained without deterioration. The above-mentioned technical concepts may have the same advantages in the process in which the back-side pad structures 50 are in directly bonded to each other and in the process in which the lower and upper front-side pad structures 40L and 40U and the back-side pad structures 50 are in directly bonded to each other.

Referring to FIG. 12D, the method may further include forming upper back-side insulating layer structures 30U and upper back-side pad structures 50U of the upper wafer 150U by performing the processes described with reference to FIGS. 11J to 11R.

Referring to FIG. 12E, the method may further include mounting the upper wafer 150U at a lower position and the lower wafer 150L at an upper position on a carrier substrate 600.

Referring to FIG. 12F, the method may further include forming lower back-side insulating layers 30L and lower back-side pad structures 50L of the lower wafer 150L by performing the processes described with reference to FIGS. 11J to 11R. A wafer bonding structure 150 including the lower wafer 150L and the upper wafer 150U may be formed.

Referring to FIG. 12G, the method may further include separating the wafer bonding structure 150 into a plurality of semiconductor die stack units 200 by performing a singulation process. The singulation process may include a stealth dicing process and/or a sawing process. Thereafter, the method may further include separating the semiconductor die stack units 200 from the carrier substrate 600.

The semiconductor die stack unit 200A shown in FIG. 7A may be formed by a wafer-to-wafer (or wafer-on-wafer) bonding method. According to the embodiment, the wafer bonding structure 150 is formed by bonding the lower wafer 150L and the upper wafer 150U, and then the wafer bonding structure 150 is separated into individual semiconductor die stack units 200A, so that productivity can increase. That is, because each of the alignment process and the bonding process is performed only once, the forming process for forming the semiconductor die stack units 200A can be simplified and the productivity of the semiconductor die stack units 200A may be increased.

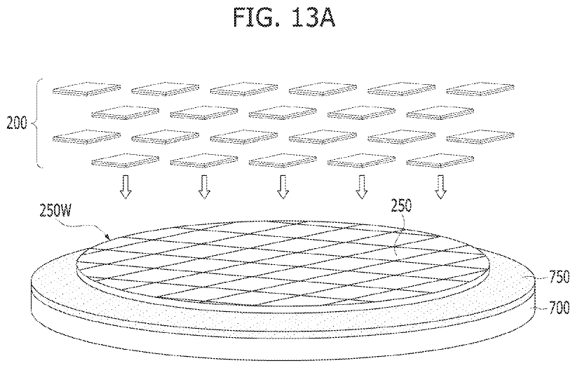

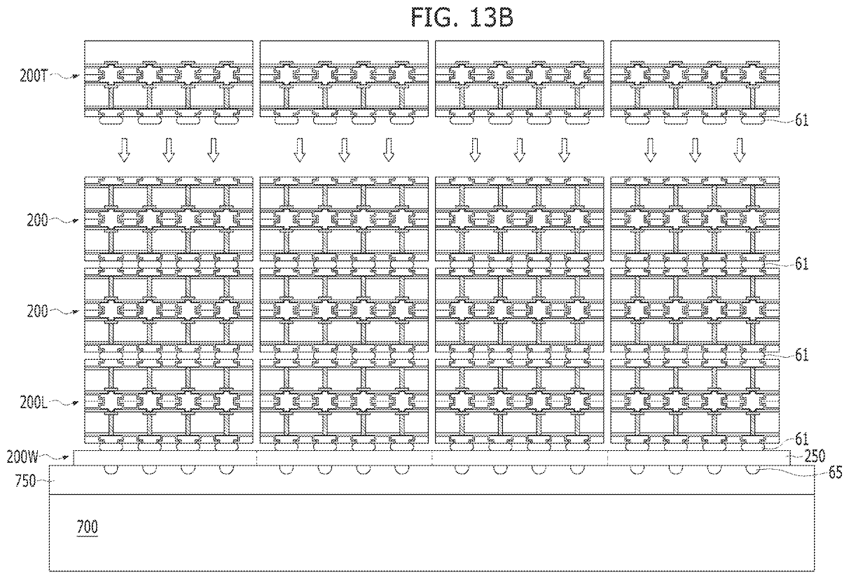

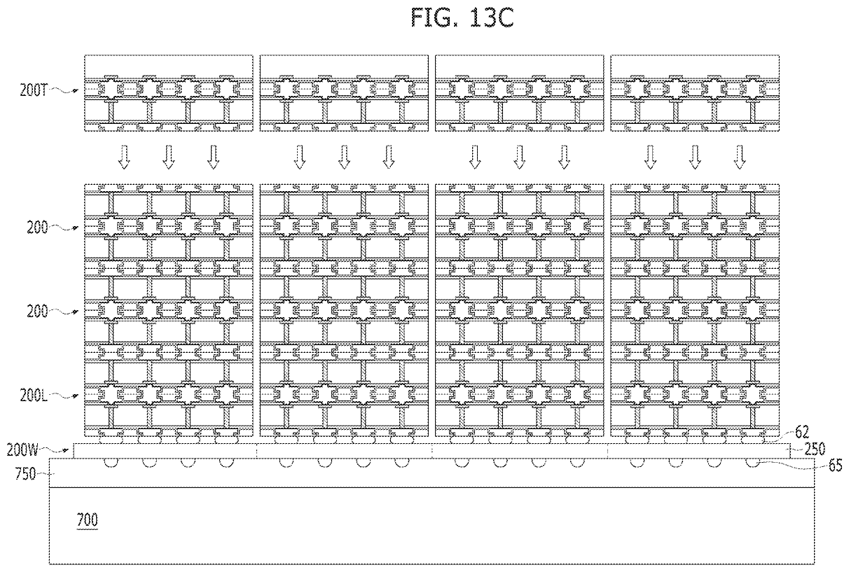

FIGS. 13A to 13C are side cross-sectional views illustrating methods of forming semiconductor die stack structures according to embodiments of the present disclosure. Referring to FIGS. 13A and 13B, the method of forming the semiconductor die stack structure may include stacking semiconductor die stack units 200L, 200, and 200T on a base die wafer 200W mounted on a carrier substrate 700 in a chip-to-wafer bonding method. Inter-unit connectors 61 may be provided between pad structures 40 and 50 of the semiconductor die stack units 200L, 200, and 200T. A wafer support system 750 may be disposed on the carrier substrate 700 to protect the base die connectors 65. The base die wafer 200W may include a plurality of base dies 250. Thereafter, the method may further include forming the semiconductor die stack structure 300A illustrated in FIG. 9A by performing a separation process. In addition, the method may further include forming the heat dissipation molding layer 80 to form the semiconductor die stack structure 300C shown in FIG. 9C.

Referring to FIGS. 13A and 13C, the method of forming a semiconductor die stack structure may include stacking the semiconductor die stack units 200L, 200, and 200T on the base die wafer 200W mounted on the carrier substrate 700 by a hybrid bonding method. The pad structures 40 and 50 of the semiconductor die stack units 200L, 200, and 200T may be directly in contact with and bonded to each other. Thereafter, the method may further include performing a separation process to form the semiconductor die stack structure 300B shown in FIG. 9B. The method may further include forming the heat dissipation molding layer 80 to form the semiconductor die stack structure 300D shown in FIG. 9D.

According to technical concepts of the present disclosure, because the plurality of semiconductor die stack units 200L, 200, and 200T may be stacked on the wafer level base die 250, the alignment process may be simplified and the bonding process may be integrally performed, so that productivity can increase.

According to some embodiments of the present disclosure, a semiconductor die, a semiconductor die stack unit, a semiconductor die stack structure, and a high-bandwidth memory include pads having an enlarged volume. Accordingly, heat dissipation and bonding stability can be improved.

According to some embodiments of the present disclosure, methods of manufacturing the semiconductor die including pads having an enlarged volume, the semiconductor die stack having the semiconductor die, the semiconductor die stack structure having the semiconductor die stack, and the high-bandwidth memory having the semiconductor die stack structure.

While the present disclosure has been described with respect to the specific embodiments, it will be apparent to those skilled in the art that various changes and modifications may be made without departing from the spirit and scope of the present disclosure as defined in the following claims.

What is claimed is:

1. A semiconductor die stack structure comprising:
a base die;
a plurality of semiconductor die stack units stacked over the base die; and
bumps between the base die and the plurality of semiconductor die stack units and between the plurality of semiconductor dies stack units,
wherein each of the plurality of semiconductor die stack units includes a lower semiconductor die and an upper semiconductor die stacked over the lower semiconductor die,
wherein each of the lower semiconductor die and the upper semiconductor die includes:
a body having a front-side and a back-side; and
a front-side pad structure disposed over the front-side of the body,
wherein the front-side pad structure includes:
a front-side pad seed layer; and
a front-side pad pattern over the front-side pad seed layer,
wherein the front-side pad pattern includes:
a first front-side pad portion having a plate shape;
a second front-side pad portion over the first front-side pad portion, wherein the first front-side pad portion and the second front-side pad portion forms a staircase; and
a third front-side pad portion under the first front-side pad portion, wherein the first front-side pad portion and the third front-side pad form a reverse staircase,
wherein the first front-side pad portion, the second front-side pad portion, and the third front-side pad include a same metal.

2. The semiconductor die stack structure of claim 1,
wherein each of the lower semiconductor die and the upper semiconductor die further comprises:
a back-side passivation layer under the back-side of the body; and
a back-side pad structure under the back-side passivation layer,
wherein the back-side pad structure includes a back-side pad seed layer under the back-side of the body, and a back-side pad pattern under a lower surface of the back-side pad seed layer,
wherein the back-side pad pattern includes:
a first back-side pad structure having a plate shape; and
a second back-side pad portion under the first back-side pad portion, wherein the first back-side pad portion and the second back-side pad portion form a reverse staircase,
wherein the first back-side pad portion, the second back-side pad portion, and the third back-side pad pattern include a same metal.

3. The semiconductor die stack structure of claim 2,
wherein each of the lower semiconductor die and the upper semiconductor die further comprises:
a back-side pad liner layer conformally surrounding a side surface and a lower surface of the first back-side pad portion and a side surface of the second back-side pad portion; and
a back-side bonding insulating layer under the back-side pad liner layer,
wherein a lower surface of the second back-side pad portion, a lower end of the back-side pad liner layer, and a lower surface of the back-side bonding insulating layer are co-planar.

4. The semiconductor die stack structure of claim 3, wherein:
a width of the second front-side pad portion is different from a width of the second back-side pad portion in a first horizontal direction, and
a width of the second front-side pad portion is different from a width of the second back-side pad portion in a second horizontal direction,
wherein the first horizontal direction and the second horizontal direction are perpendicular with each other.

5. The semiconductor die stack structure of claim 3, wherein:
the second front-side pad portion of the lower semiconductor die is directly in contact with and bonded to the second back-side pad portion of the upper semiconductor die, and
the front-side bonding insulating layer of the lower semiconductor die is directly in contact with and bonded to the back-side bonding insulating layer of the upper semiconductor die.

6. The semiconductor die stack structure of claim 2,
wherein each of the lower semiconductor die and the upper semiconductor die further comprises:
a top metal pattern disposed in the body to be adjacent to the front-side of the body; and
a front-side passivation layer over the front-side of the body to expose an upper surface of the top metal pattern.

7. The semiconductor die stack structure of claim 6,
wherein the front-side pad seed layer includes:
a first-side pad seed portion disposed over an upper surface of the front-side passivation;
a second front-side pad seed portion disposed over a side surface of the front-side passivation layer; and
a third front-side pad seed portion disposed over the exposed upper surface of the top metal pattern.

8. The semiconductor die stack structure of claim 6,
wherein each of the lower semiconductor die and the upper semiconductor die further comprises:
a front-side pad liner layer conformally surrounding a side surface and an upper surface of the first front-side pad portion and a side surface of the second front-side pad portion; and
a front-side bonding insulating layer over the front-side pad liner layer,
wherein an upper surface of the second front-side pad portion, an upper end of the front-side pad liner layer, and an upper surface of the front-side bonding insulating layer are co-planar.

9. The semiconductor die stack structure of claim 6,
wherein each of the lower semiconductor die and the upper semiconductor die further comprises a through-via passing through the body to electrically connect the top metal pattern to the back-side pad structure.

10. The semiconductor die stack structure of claim 9,
wherein each of the lower semiconductor die and the upper semiconductor die further comprises:
a dummy front-side pad structure disposed over the front-side of the body, wherein the dummy front-side pad structure is not electrically connected to the through-via,
wherein the dummy front-side pad structure includes:
a dummy front-side pad seed layer; and
a dummy front-side pad pattern over the dummy front-side pad seed layer,
wherein the dummy front-side pad pattern includes:
a first dummy front-side pad portion having a plate shape;
a second dummy front-side pad portion over the first dummy front-side pad portion, wherein the first dummy front-side pad portion and the second dummy front-side pad portion form a staircase; and
a third dummy front-side pad portion under the first dummy front-side pad portion, wherein the first dummy front-side pad portion and the third dummy front-side pad portion form a reverse staircase,
wherein the first dummy front-side pad portion, the second dummy front-side pad portion, the third dummy front-side pad portion includes a same metal.

11. The semiconductor die stack structure of claim 10,
wherein each of the lower semiconductor die and the upper semiconductor die further comprises:
a dummy back-side pad structure under the back-side passivation layer, wherein the dummy back-side pad structure is not electrically connected to the through-via,
wherein the dummy back-side pad structure includes:
a dummy back-side pad seed layer over the back-side of the body; and
a dummy back-side pad pattern under the dummy back-side pad seed layer,
wherein the dummy back-side pad pattern includes:
a first dummy back-side pad portion having a plate shape; and
a second dummy back-side pad portion under the first dummy back-side pad portion, wherein the first dummy back-side pad portion and the second dummy back-side pad portion form a reverse staircase,
wherein the first dummy back-side pad portion and the second back-side pad portion include a same metal.

12. The semiconductor die of stack structure claim 9, wherein:
the front-side pad structure includes a signal front-side pad structure and a power front-side pad structure;
the back-side pad structure includes a signal back-side pad structure and a power back-side pad structure,
the top metal pattern includes a signal top metal pattern and a power top metal pattern,
the through-via includes a signal through-via and a power through-via, and
the power through-via includes a plurality of unit power through-vias electrically and commonly connecting the power top metal pattern to the power back-side pad structure.

13. The semiconductor die stack structure of claim 1, further comprising:
heat dissipation molding layers disposed between the base die and the plurality of semiconductor die stack units and between the plurality of semiconductor die stack units, wherein the heat dissipation molding layers surround side surfaces of the bumps,
wherein each of the bumps includes a solder ball,
wherein each of the heat dissipation molding layers includes an epoxy resin and aluminum fillers.

14. A semiconductor die stack structure comprising:
a base die;
a plurality of semiconductor die stack units stacked over the base die; and
bumps between the base die and the plurality of semiconductor die stack units and between the plurality of semiconductor die stack units,
wherein each of the plurality of semiconductor die stack units includes a lower semiconductor die and an upper semiconductor die stacked over the lower semiconductor die,
wherein each of the lower semiconductor die and the upper semiconductor die includes:
a body having a front-side and a back-side; and
a back-side passivation layer under the back-side of the body; and
a back-side pad structure under the back-side passivation layer,
wherein the back-side pad structure includes:
a back-side pad seed layer under the back-side of the body; and
a back-side pad pattern under the back-side pad seed layer,
wherein the back-side pattern includes:
a first back-side pad portion having a plate shape; and
a second back-side pad portion under the first back-side pad portion, wherein the first back-side pad portion and the second back-side pad portion form a reverse staircase,
wherein the first back-side pad portion and the second back-side pad portion include a same metal.

15. The semiconductor die stack structure of claim 14,
wherein each of the lower semiconductor die and the upper semiconductor die further comprises:
a back-side pad liner layer conformally surrounding a side surface and a lower surface of the first back-side pad portion and a side surface of the second back-side pad portion; and
a back-side bonding insulating layer under the back-side pad liner layer,
wherein a lower surface of the second back-side pad portion, a lower end of the back-side liner layer, and a lower surface of the back-side bonding layer are co-planar.

16. The semiconductor die stack structure of claim 14,
wherein each of the lower semiconductor die and the upper semiconductor die further comprises a front-side pad structure disposed over the front-side of the body,
wherein the front-side pad structure includes:
a front-side pad seed layer; and
a front-side pad pattern over the front-side pad seed layer,
wherein the front-side pad pattern includes:
a first front-side pad portion having a plate shape;
a second front-side pad portion over the first front-side pad portion, wherein the first front-side pad portion and the second front-side pad portion form a staircase,
a third front-side pad portion under the first front-side pad portion, wherein the first front-side pad portion and the third front-side pad portion form a reverse staircase,
wherein the first front-side pad portion, the second front-side pad portion, and the third front-side pad portion include a same metal.

17. The semiconductor die stack structure of claim 16,
wherein each of the lower semiconductor die and the upper semiconductor die further comprises:
a top metal pattern disposed in the body to be adjacent to the front-side of the body; and
a front-side passivation layer disposed over the front-side of the body, wherein the front-side passivation layer exposes an upper surface of the top metal pattern.

18. The semiconductor die stack structure of claim 17,
wherein the front-side pad seed layer includes:
a first front-side pad seed portion disposed over an upper surface of the front-side passivation layer;
a second front-side pad seed portion disposed on a side surface of the front-side passivation layer; and
a third front-side seed portion disposed over the exposed upper surface of the top metal pattern.

19. The semiconductor die stack structure of claim 17,
wherein each of the lower semiconductor die and the upper semiconductor die further comprises:
a front-side pad liner layer conformally surrounding a side surface and an upper surface of the first front-side pad portion and a side portion of the second front-side pad portion; and
a front-side bonding insulating layer over the front-side pad liner layer,
wherein an upper surface of the second front-side pad portion, an upper end of the front-side pad liner layer, and an upper surface of the front-side bonding insulating layer are co-planar.

20. The semiconductor die stack structure of claim 14, wherein:
the second front-side pad portion of the lower semiconductor die is directly in contact with and bonded to the second front-side pad portion of the upper semiconductor die, and
the front-side bonding insulating layer of the lower semiconductor die is directly in contact with and bonded to the front-side insulating layer of the upper semiconductor die.
